(19) United States
(12) Patent Application Publication
(10) Pub. No.: US 2026/0370144 A1
(43) Pub. Date: Nov. 19, 2026

(54) FULLY DIFFERENTIAL LEVEL SHIFT IN A NOISY ENVIRONMENT

(71) Applicant: pSemi Corporation, San Diego, CA (US)

(72) Inventors: Antony Routledge, Basingstoke (GB); Satish Vangara, Woodley (GB)

(21) Appl. No.: 19/735,318

(22) Filed: Jul. 8, 2026

Related U.S. Application Data
(63) Continuation of application No. PCT/US2025/011001, filed on Jan. 9, 2025.
(60) Provisional application No. 63/620,331, filed on Jan. 12, 2024.

(51) Int. Cl. H02M 3/158

(52) U.S. Cl. CPC H02M 3/158

(57) ABSTRACT

Circuits and methods are provided that more effectively and efficiently implement multi-level converter circuits, including circuits and methods that more effectively and efficiently transform a differential voltage in an upper voltage domain to a level-shifted differential voltage in a lower voltage domain. First and second signals are applied to a differential amplifier in the upper voltage domain to provide a pair of amplified voltages representing a differential amplified voltage. First and second level shifters are provided for translating each of the pair of amplified voltages to first and second output voltages, respectively, relative to a reference potential. The first and second output voltages collectively correspond to a differential level-shifted output voltage relative to the reference potential. The differential level-shifted output voltage may be applied to a fully-differential analog to digital converter.

### CROSS-REFERENCE TO RELATED APPLICATIONS

This patent application is a continuation of International Patent Application No. PCT/US2025/011001 filed Jan. 9, 2025 and entitled “FULLY DIFFERENTIAL LEVEL SHIFT IN A NOISY ENVIRONMENT,” which claims the benefit of and priority to U.S. Provisional Patent Application No. 63/620,331 filed Jan. 12, 2024 and entitled “FULLY DIFFERENTIAL LEVEL SHIFT IN A NOISY ENVIRONMENT,” which are incorporated herein by reference in their entirety.

This patent application and International Patent Application No. PCT/US2025/011001 filed Jan. 9, 2025 and entitled “FULLY DIFFERENTIAL LEVEL SHIFT IN A NOISY ENVIRONMENT” are related to the following United States Provisional Patent Applications filed on Jan. 12, 2024, which are all incorporated herein by reference in their entirety:

Application No. 63/620,507 entitled “LEVEL SHIFTER AND BOOT CAPACITOR CIRCUITS, SYSTEMS, AND METHODS;”

Application No. 63/620,623 entitled “LEVEL SHIFTER AND BOOT CAPACITOR CIRCUITS, SYSTEMS, AND METHODS;”

Application No. 63/620,613 entitled “INTEGRATED CURRENT RESISTOR SENSING FOR MULTI-LEVEL CONVERTER;”

Application No. 63/620,465 entitled “STARTUP INTERLOCK FOR POWER CONVERTER CIRCUITS;”

Application No. 63/620,331 entitled “FULLY DIFFERENTIAL LEVEL SHIFT IN A NOISY ENVIRONMENT;”

Application No. 63/620,450 entitled “CAPACITOR SENSING AND CAPACITOR BALANCING SYSTEMS AND METHODS;”

Application No. 63/620,469 entitled “CAPACITOR SENSING AND CAPACITOR BALANCING SYSTEMS AND METHODS;”

Application No. 63/620,678 entitled “RECONFIGURABLE MULTI-LEVEL POWER CONVERTER TO CHARGE PUMP MODE AND FRACTIONAL CHARGE PUMP MODE;”

Application No. 63/620,417 entitled “INPUT CURRENT SLEW FOR A MULTI-LEVEL CONVERTER;”

Application No. 63/620,726 entitled “ADJUSTING OVERVOLTAGE PROTECTION BASED ON MODE OF OPERATION SYSTEMS AND METHODS;”

Application No. 63/620,737 entitled “HYBRID PEAK AVERAGE CURRENT MODE CONTROL;”

Application No. 63/620,741 entitled “CURRENT LIMITED VOLTAGE MODE CONTROL OF MULTIPLE INPUTS;”

Application No. 63/620,527 entitled “MULTI-FUNCTION COMP PIN SYSTEMS AND METHODS;”

Application No. 63/620,488 entitled “LEVEL SHIFTER AND BOOT CAPACITOR CIRCUITS, SYSTEMS, AND METHODS;”

Application No. 63/620,553 entitled “MULTI-LEVEL REVERSE CURRENT BLOCKING SYSTEMS AND METHODS;”

Application No. 63/620,638 entitled “GENERAL STARTUP FOR MULTI-LEVEL POWER CONVERTER CIRCUITS;”

Application No. 63/620,733 entitled “PRECISION ANALOG TO DIGITAL CIRCUIT TUNED VOLTAGE AND CURRENT MODE DC-DC CONVERTER;”

Application No. 63/620,738 entitled “PREDICTIVE CONTROL LOOP PRE-CHARGING DURING A MULTI-LEVEL ZONE CHANGE;”

Application No. 63/620,764 entitled “DETECTOR CIRCUIT FOR DETECTING ONE OF MULTI-INPUT CONTROLLING SIGNALS THAT CONTROLS A CONTROL LOOP CIRCUIT;”

Application No. 63/620,607 entitled “STARTUP VOLTAGE SELECTION FOR MULTI-LEVEL POWER CONVERTER CIRCUITS;”

Application No. 63/620,575 entitled “MULTI-LEVEL CAPACITOR FAULT DETECTION SYSTEMS AND METHODS;”

Application No. 63/620,582 entitled “PARELLEL OPERATION OF MULTI-LEVEL POWER CONVERTERS;” and

Application No. 63/620,763 entitled “AVERAGE AND PEAK CURRENT SENSE SYSTEMS AND METHODS.”

### BACKGROUND

This disclosure relates to electronic circuits, and more particularly for example to multi-level power converters.

Many electronic products, including mobile computing and/or communication products and components (e.g., notebook computers, ultra-book computers, tablet devices, LCD, LED displays, and the like) use multiple voltage levels for operation. For example, radio frequency (RF) transmitter power amplifiers may operate at relatively high voltages (e.g., 12V or more), whereas logic circuitry may operate at a relatively low voltage level (e.g., 1-3V) and other circuitry may operate at an intermediate voltage level (e.g., 5-10V).

Direct current power converters are often used to generate a lower or higher voltage from a common power source, such as a battery, solar cells, and rectified AC sources. Power converters which generate a lower output voltage level from a higher input voltage power source are commonly known as buck converters, so-called because the output voltage VOUT is less than the input voltage V_{IN}, and hence the converter is “bucking” the input voltage. Power converters which generate a higher output voltage level from a lower input voltage power source are commonly known as boost converters, because V_{OUT} is greater than V_{IN}. Some power converters may be either a buck converter or a boost converter depending on which terminals are used for input and output. Some power converters may provide an inverted output.

One type of direct current power converter known as a multi-level power converter includes charge transfer capacitors as energy storage elements coupled by controlled switches to transfer charge from V_{IN} to V_{OUT}. Such charge transfer capacitors are commonly known as “fly capacitors” or “pump capacitors”. When a fly capacitor is used (i.e., not bypassed), the electrical energy flowing through that fly capacitor generally will either charge it or discharge it.

There is a continued need for improved circuits and methods for more effectively and efficiently operating and implementing various type of electrical circuits and devices, including for example multi-level converter circuits.

### SUMMARY

Embodiments of the present disclosure include systems, circuits, and methods for operating and implementing various electronics circuits, including multi-level converter circuits.

One embodiment encompasses a circuit including a differential amplifier configured to operate from a first supply voltage. The differential amplifier includes first and second terminals configured to receive corresponding first and second signals, respectively. The differential amplifier also includes third and fourth terminals configured to provide a differential amplified voltage thereacross. A first level shifter includes a first terminal coupled to the third terminal of the differential amplifier, and a second terminal configured to provide a first output voltage relative to a reference potential. Similarly, a second level shifter includes a first terminal coupled to the fourth terminal of the differential amplifier, and a second terminal configured to provide a second output voltage relative to the reference potential. The first output voltage and the second output voltage collectively correspond to a differential level-shifted output voltage relative to the reference potential. In at least some embodiments, the circuit includes a switched-mode power converter having a first terminal configured to receive an input current from an input voltage source, and further includes a resistive element coupled between the input voltage source and the first terminal of the switched mode power converter. The resistive element is configured to conduct input current drawn by the first terminal of the switched mode power converter, and the opposing ends of resistive element are configured to be coupled to the first and second terminals of the differential amplifier.

Another embodiment encompasses a method which includes applying a voltage across first and second terminals of a differential amplifier to produce a differential output voltage across third and fourth terminals thereof. The differential amplifier operates in an upper voltage domain proximate an upper voltage source. The differential amplifier provides a third terminal voltage at its third terminal, and provides a fourth terminal voltage at its fourth terminal. The method further includes level-shifting the voltage at the third terminal of the differential amplifier to a first level-shifted voltage in a lower voltage domain proximate to a reference potential. The method also includes level-shifting the voltage at the fourth terminal of the differential amplifier to a second level-shifted voltage in the lower voltage domain proximate to the reference potential. The first and second level-shifted voltages collectively provide a differential output voltage in the low voltage domain. In at least some of such embodiments, the method includes providing a switched-mode power converter having a first terminal for drawing input current from an input voltage source and providing a resistive element between the input voltage source and the first terminal of the switched mode power converter for conducting input current drawn by the first terminal of the switched mode power converter. The method further includes applying the differential voltage created across the resistive element to the first and second terminals of the differential amplifier.

A further embodiment encompasses a system including a battery to be charged, and a switched-mode power converter having a first terminal configured to receive an input current from an input voltage source, and a second terminal configured to charge the battery. The system includes a resistive element coupled between the input voltage source and the first terminal of the switched mode power converter, the resistive element configured to conduct input current drawn by the first terminal of the switched mode power converter. A differential amplifier is configured to operate from a first supply voltage and includes first and second terminals for receiving corresponding first and second signals. The differential amplifier includes third and fourth terminals configured to provide a differential amplified voltage thereacross. The first and second terminals of the differential amplifier are configured to be coupled across the opposing sides of the resistive element. The system includes a first level shifter having a first terminal coupled to the third terminal of the differential amplifier, and having a second terminal configured to provide a first output voltage relative to a reference potential. Similarly, the system includes a second level shifter having a first terminal coupled to the fourth terminal of the differential amplifier, and having a second terminal configured to provide a second output voltage relative to a reference potential. The first output voltage and second output voltage collectively provide a differential level-shifted output voltage relative to the reference potential, the differential level-shifted output voltage corresponding to input current drawn by the first terminal of the switched mode power converter.

The scope of the present disclosure is defined by the claims, which are incorporated into this section by reference. A more complete understanding of embodiments of the present disclosure will be afforded to those skilled in the art, as well as a realization of additional advantages thereof, by a consideration of the following detailed description of one or more embodiments. Reference will be made to the appended sheets of drawings that will first be described briefly.

### DESCRIPTION OF THE DRAWINGS

FIG. 1A is an example power converter circuit with internal input current sense, in accordance with one or more embodiments of the present disclosure.

FIG. 1B is an example power converter circuit with external input current sense, in accordance with one or more embodiments of the present disclosure.

FIG. 2A is an example dual integrated circuit (IC) power converter circuit with internal input current sense, in accordance with one or more embodiments of the present disclosure.

FIG. 2B is an example dual IC power converter circuit with external input current sense, in accordance with one or more embodiments of the present disclosure.

FIG. 3A is an example functional block diagram of a power converter circuit, in accordance with one or more embodiments of the present disclosure.

FIG. 3B is an example functional block diagram of a power converter circuit, in accordance with one or more embodiments of the present disclosure.

FIG. 4 is a diagram illustrating an example charging function in step down regulation mode of an example power converter circuit, in accordance with one or more embodiments of the present disclosure.

FIG. 5 is a diagram illustrating an example charging function in step down divide by 3 charge pump mode, in accordance with one or more embodiments of the present disclosure.

FIG. 6 is a functional block diagram illustrating aspects of an example power converter circuit, in accordance with one or more embodiments of the present disclosure.

FIG. 7 is a block diagram illustrating an example system implementing a power converter circuit, in accordance with one or more embodiments of the present disclosure.

FIG. 8A is a circuit diagram illustrating an example 3-level converter circuit, in accordance with one or more embodiments of the present disclosure.

FIG. 8B is a circuit diagram illustrating an example 4-level converter circuit, in accordance with one or more embodiments of the present disclosure.

FIG. 8C is a circuit diagram illustrating an example M-level converter circuit, in accordance with one or more embodiments of the present disclosure.

FIG. 9 is an example M-level converter circuit, in accordance with one or more embodiments of the present disclosure.

FIG. 10 is a block diagram of an example embodiment of control circuitry for an M-level converter cell, in accordance with one or more embodiments of the present disclosure.

FIG. 11 is a functional block diagram illustrating an example of differential level shifting of a voltage in an upper voltage domain to a differential voltage in a lower voltage domain, in accordance with one or more embodiments of the present disclosure.

FIG. 12 is a circuit diagram illustrating an example of a differential amplifier for amplifying a differential input voltage in an upper voltage domain, in accordance with one or more embodiments of the present disclosure.

FIG. 13 is a circuit diagram illustrating a first example of a level shifting circuit for shifting a voltage signal from an upper voltage domain to a lower voltage domain, in accordance with one or more embodiments of the present disclosure.

FIG. 14 is a circuit diagram illustrating a second example of a level shifting circuit for shifting a voltage signal from an upper voltage domain to a lower voltage domain, in accordance with one or more embodiments of the present disclosure.

FIG. 15 is a circuit diagram illustrating an example of buffer amplifiers coupling level shifted differential voltage signals to a fully differential analog-to-digital converter, in accordance with one or more embodiments of the present disclosure.

FIG. 16 is a flowchart illustrating a method for level shifting a differential voltage in an upper voltage domain to differential inputs of an analog-to-digital converter in a lower voltage domain, in accordance with one or more embodiments of the present disclosure.

Embodiments of the present disclosure and their advantages are best understood by referring to the detailed description that follows. It is noted that sizes of various components and distances between these components are not drawn to scale in the figures. It should be appreciated that like reference numerals are used to identify like elements illustrated in one or more of the figures.

### DETAILED DESCRIPTION

The present disclosure encompasses novel circuits, architectures, systems, and methods that more effectively and efficiently address the configuration and operation of multi-level converter circuits. It will be appreciated that various improvements disclosed herein encompass innovative circuits, hardware components, architectures, and related logic that are applicable to applications beyond multi-level converter circuits.

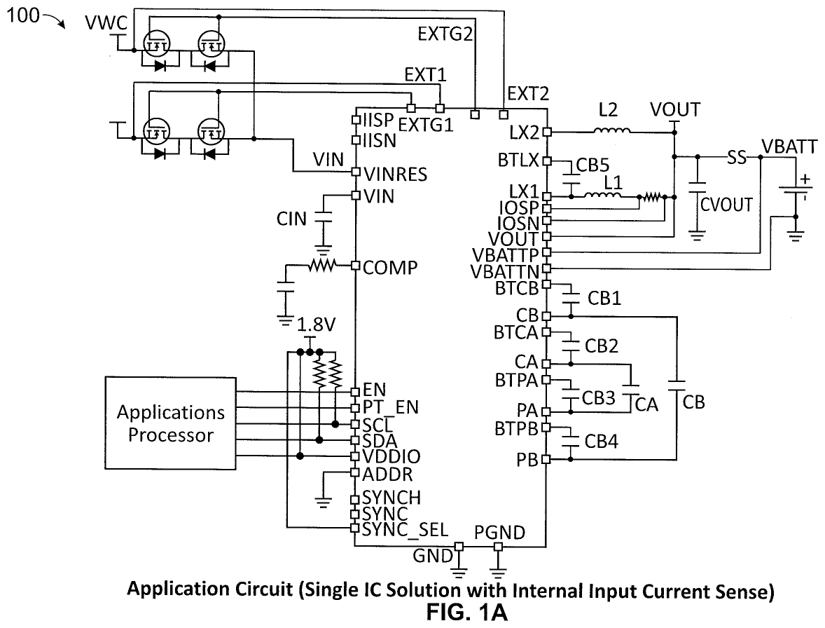

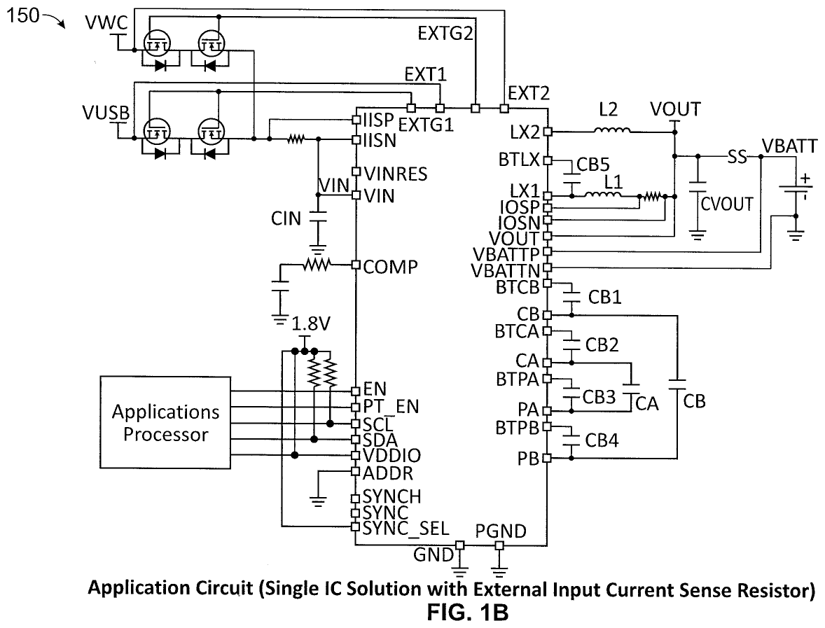

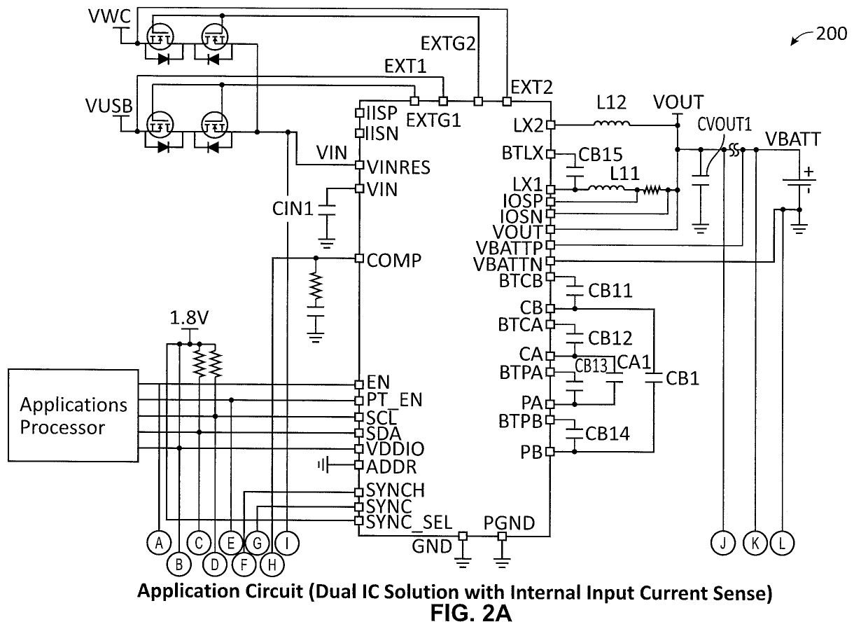

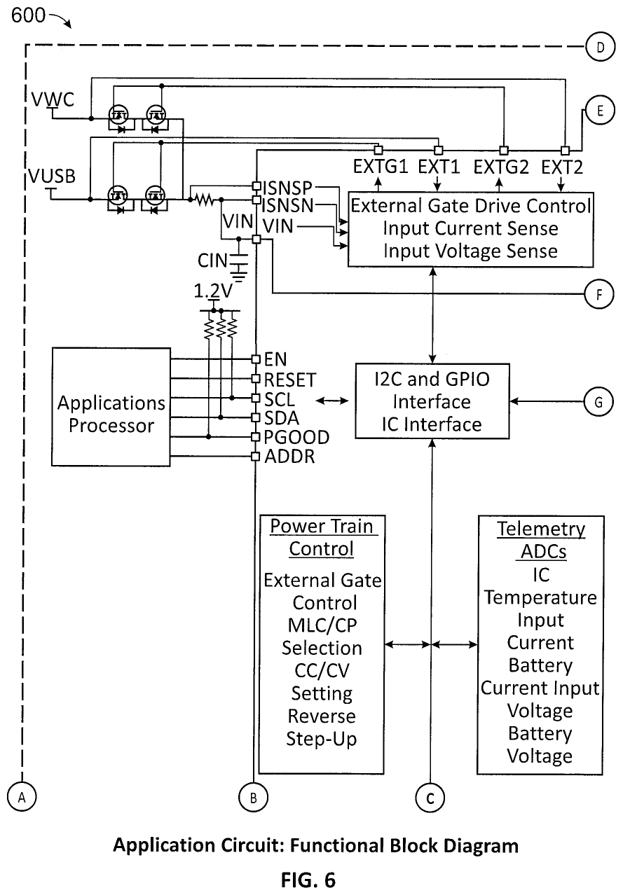

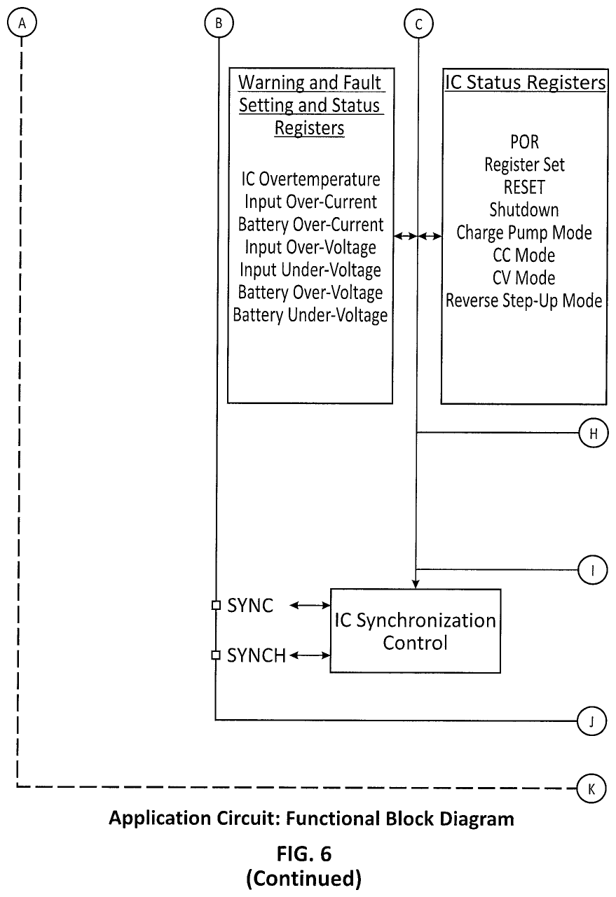

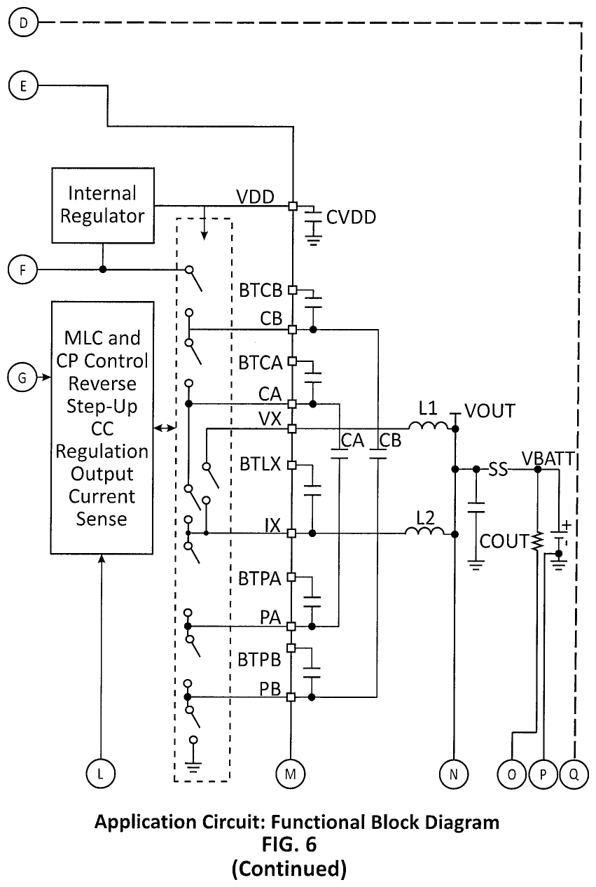

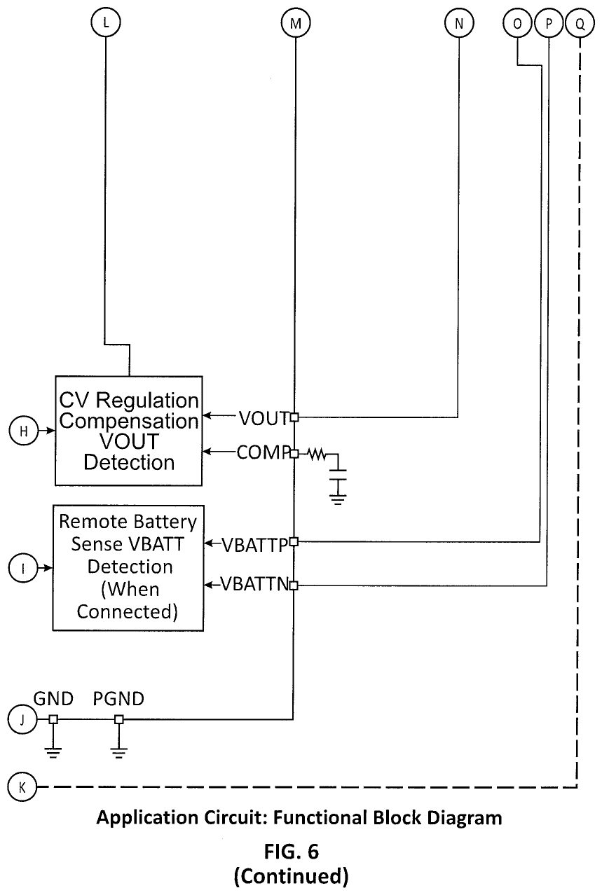

FIGS. 1-6 illustrate various embodiments of a high efficiency 4-level step-down and step-up power converter for battery charging applications, such as single cell Li-ion and Li-polymer battery applications. In the illustrated embodiments, the power converter is configured to deliver up to 5 amperes (A) of charging current in regulation mode and in a divide-by-3 charge pump mode, though other configurations are within the scope of the present disclosure. The power converter can be configured, for example, into dual ICs operation for 9 A charging current in regulation mode and in divide-by-3 charge pump mode. Although a 4-level power converter is illustrated, it will be appreciated that the embodiments described herein may be applicable to various M-level implementations, where M>=3.

In some implementations, for example, the power converter may supply an input range of approximately 4.5 V to 18 V input to support both universal serial bus (USB) and wireless inputs, and in a reverse step-up mode, the output may be programmable from 4.8 V to 16 V in 100 mV step with a programmable output current limit up to 1.7 A. This input voltage range may be used, for example, to support fast charging of single Li-Ion cells from USB and wireless input. It will be appreciated that other voltage and current ranges and limits may be implemented depending on the application. It will also be appreciated that while compatibility with USB is described herein, other wired interfaces and protocols may be implemented with the power converter of the present disclosure.

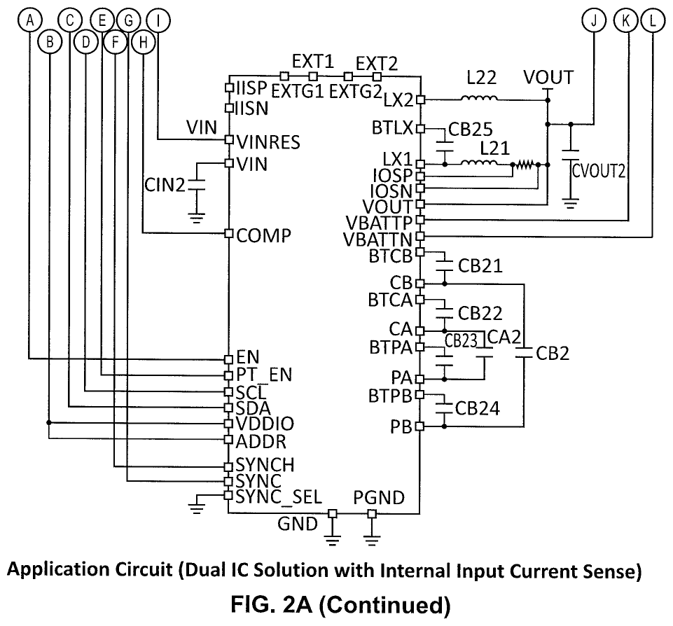

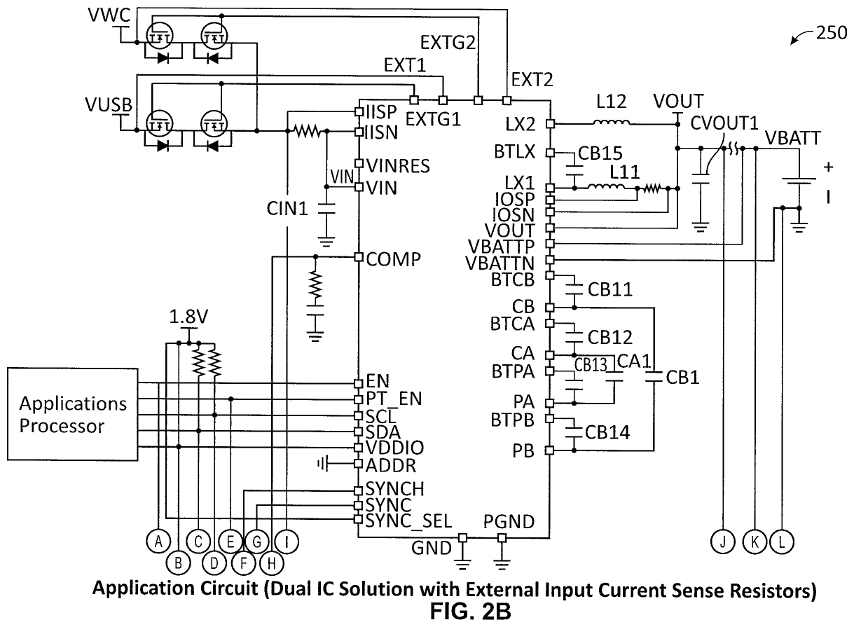

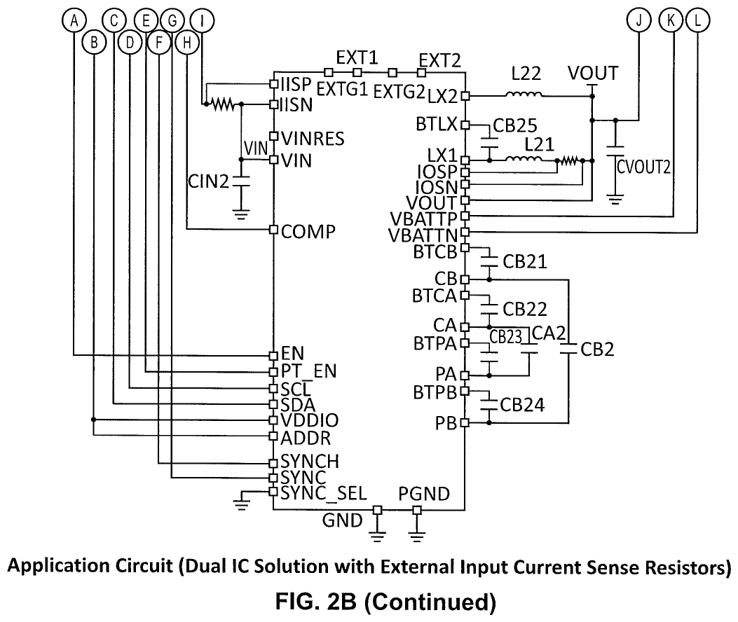

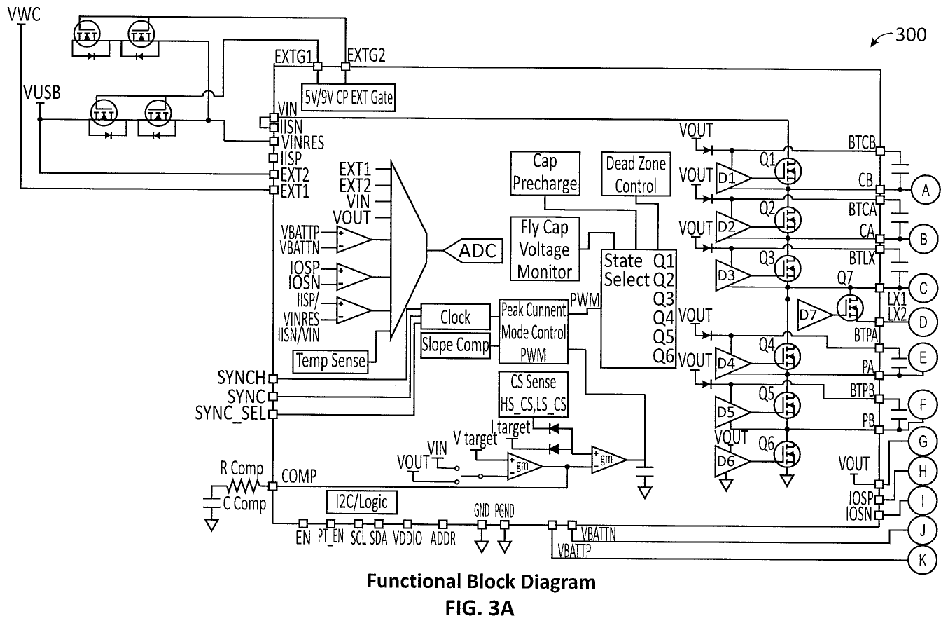

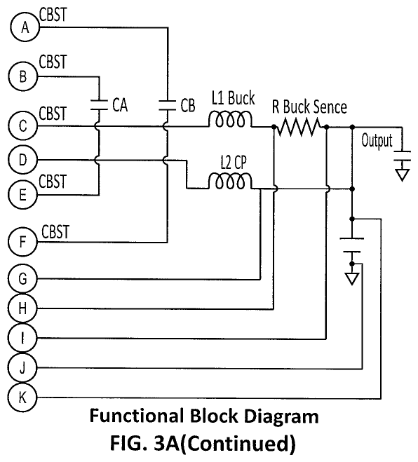

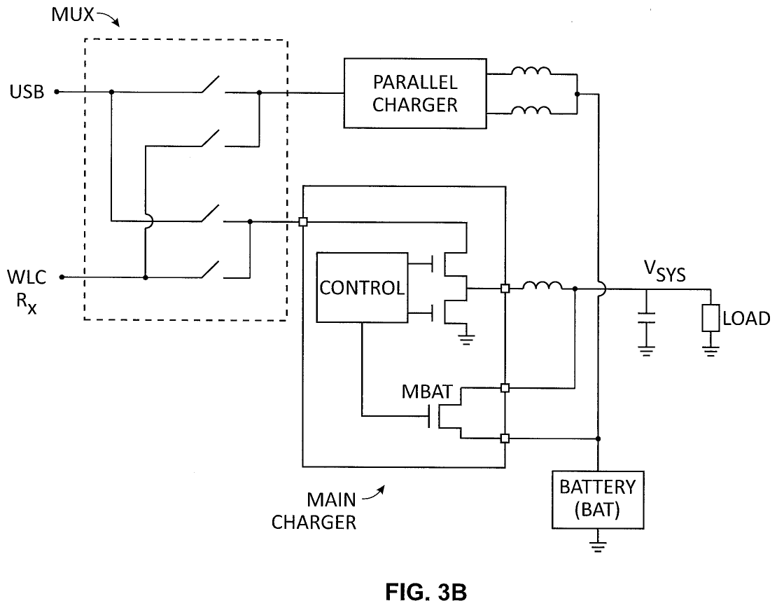

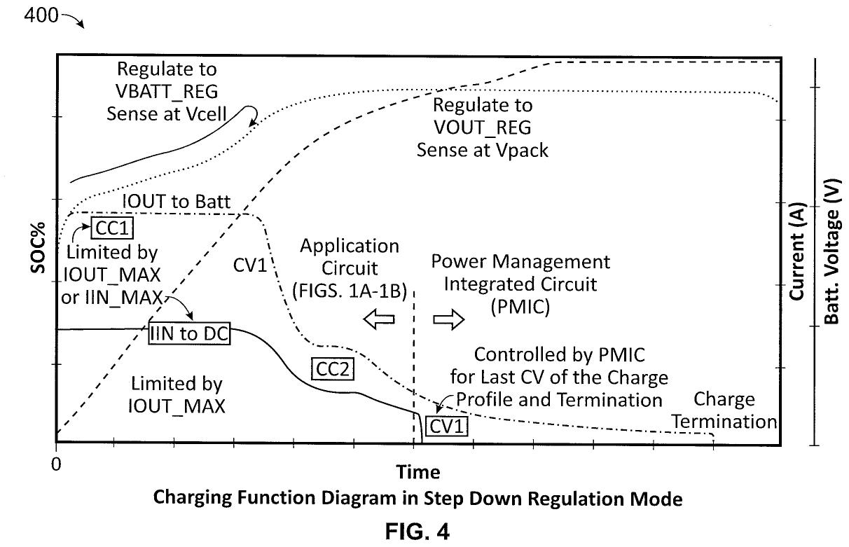

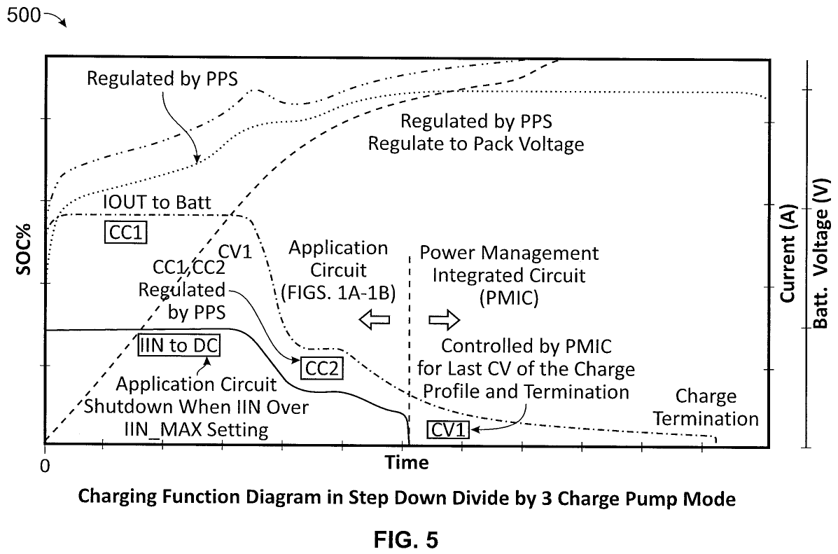

In various embodiments, the power converter may be implemented as a single integrated circuit (IC) (see, e.g., FIGS. 1A-B), dual-integrated circuits (see, e.g., FIGS. 2A-B), or in other configurations depending on the implementation. In various embodiments, the power converter may operate as a parallel charger along with a main charger, as shown in FIG. 3B, to provide the desired functionality noted herein and, for example, as illustrated in FIGS. 4 and 5 for the desired charging functionality for various applications, as would be understood by one skilled in the art. FIG. 3B may represent a system level point of view of a mobile architecture having a parallel charger and a main charger that accepts power from a wired port (e.g., a wired USB) or from a wireless interface. The parallel charger for one or more embodiments may represent an IC as illustrated in FIGS. 1-3A, for example, and may function to charge a battery for some portion of the charging profile (e.g., as shown in FIGS. 4 and 5), while the main charger charges the battery for other portions of the charging profile. In various embodiments, the parallel charger may also be configured to function as the main charger as well, depending upon the desired application. The novel architecture disclosed herein may be implemented to enable (i) improved efficiency (e.g., at 9 A charging current) in a low-profile solution; (ii) low electromagnetic interference (EMI) fixed-frequency operation under heavy load conditions; (iii) input and output current and voltage, IC temperature monitoring and telemetry via inter-integrated circuit (I₂C) technology; and/or (iv) full protection including input and output under voltage lockout (UVLO), input and output over voltage protection (OVP), input and output over current protection (OCP), and IC over-temperature with fault and warning status. In some implementations, the power converter supports divide-by-3, step-down and step-up regulating modes, dual external disconnect switch control, and/or paralleled operation.

In the illustrated embodiments, the power converter is implemented as a multi-level charge pump incorporating power switches and control circuitry. The power converter's internal bias may be provided by the system battery through a VOUT connection (e.g., pin). The charging input can be USB (or other wired input) or wireless input by an external FET register control. In some implementations, the power converter may be programmed to different operating modes, which may include a step-down regulation mode, a step-down divide-by-3 charge pump mode, and a reverse step-up mode.

In a step-down regulation mode, the power converter operates as a multi-level step-down regulator to support USB power delivery (USB-PD) (or other wired protocol) or fixed input charging. During a constant-current (CC) phase, the maximum charging current may be limited for example, by configuring registers. When the input current does not reach a predetermined maximum input setting, the charge current is set to a predetermined maximum output setting. If the input current reaches the input maximum setting, then the charge current throttles and maintains input current at the input maximum setting. This allows maximum charging current while ensuring that the charge current does not go above a battery maximum current rating and the input current does not trip adapter over-current protection.

During a constant-voltage (CV) phase, the CV regulation may be limited, for example, by configuring registers. In operation, a single-wire sense pin or other sensor is configured to sense the output voltage VOUT, which is compared to a predetermined value stored in a register, VOUT_REG. The voltage differential between the battery's positive terminal and negative terminal is sensed and compared to a predetermined value stored in a register, VBATT_REG. In some implementations, a single-wire sense pin or other sensor senses VBATTP (battery voltage at positive terminal) and a single-wire sense pin or other sensor senses VBATTN (battery volage at negative terminal). The CV regulates to the lower of the two settings. If the VOUT sensed voltage reaches VOUT_REG first, then CV is regulated to VOUT_REG. If the VBATTP sensed voltage reaches VBATT_REG first, then CV is regulated to VBATT_REG. This provides a fast battery top off while preventing voltage above safety limit.

In a step-down divide-by-3 charge pump mode (which may be selected, for example, by setting a corresponding register), the power converter is configured as a divide-by-3 step-down charge divider to support USB-Programmable Power Supply (USB-PPS) or other charging protocol or programmable input charging. In some embodiments, the power converter allows the USB-PPS adapter to control voltage and current and ignores conflicting settings (e.g., settings stored in registers for IOUT_MAX, VOUT_REG and VBATT_REG). In this mode, the power converter monitors an IIN_MAX setting, shuts down the power train (which includes switches to configure, enable and disable various modes of operation) and disconnects external FET when IIN current exceeds IIN_MAX setting. In the illustrated embodiment, the output current is up to 10A in dual IC operation and 5 A in single IC operation.

In a reverse step-up mode (which may be selected, for example, by setting a corresponding register) the power converter is configured as a multi-level step-up regulator to power peripheral device(s) connected to USB (or other wired protocol or standard) or wireless input. The power converter draws power from the system battery and regulates V_{IN} to the VOUT_REG programmable setting of 4.8V to 16V. The VIN output current limit may be set, for example, by an IIN_MAX register.

In some embodiments, to enable the IC, both an EN pin and an IC_EN bit are set to logic high (1). When either the EN pin or IC_EN bit is set to logic low (0), the IC is disabled. After the IC is enabled, the POR status bit sets to 1 to indicate the IC has a fresh power up.

In some embodiments, the power converter provides a gate driver to control two external N-channel MOSFETs and sense inputs to monitor source input voltage at each FET. The external FETs may be controlled by registers (e.g., 1-bit registers V_EXTG, EXTG_EN and EXTGX). The V_EXTG bit sets the gate drive voltage and can be set to 9V or 5V, in the illustrated embodiment. The EXTGX bits select which FET(s) to turn on. The EXTG_EN bit enables the gate driver to turn on the selected FET(s). In various embodiments, the external FET can be turned on or off independently from other IC operations except when the IC is disabled. The EXT_EN_IND status bit set to 1 when external FET is enabled. When a fault is detected and triggers a shutdown, the external FET may be turned off automatically. If EXT1 or EXT2 detects an OVP, then the respected FET would not turn on from the off mode.

In various embodiments, the power train is enabled after all the registers have been initialized and the target input external FET is turned on. Sufficient time based on capacitance on the power path may be configured between the external FET on time and the power train on time to minimize in-rush current. Next, both PT_EN pin and PT_EN bit are set to logic high (1) to turn on the power train. When either PT_EN pin or PT_EN pin is logic low, the power train is off In dual IC operation, the slave IC power train may be configured to turn on first before the master IC. The COMP, SYNC and SYNCH pins from two ICs gate the power train and synchronize the operation. The SYNC_SEL pin sets the IC to master mode or slave mode. IC internal fault and programmable fault detection shuts down the power train operation when fault is detected.

In a reverse step-up mode (which may be selected, for example, by setting a corresponding register), the power converter is configured as a multi-level step-up regulator to power peripheral device(s) connected to USB (or other wired port) or wireless input. The power converter draws power from the system battery and regulates VIN pin to a VOUT_REG programmable setting of 4.8V to 16V. The VIN output current limit is set by IIN_MAX register.

To enable the IC, both the EN pin and IC_EN bit are set to logic high (1). When either EN pin or IC_EN bit is set to logic low (0), the IC is disabled. After the IC enables, the POR status bit sets to 1 to indicate the IC has a fresh power up. The power converter provides a gate driver to control two external N-channel MOSFETs and sense inputs to monitor source input voltage at each FET. The external FETs are controlled by register bits, such as V_EXTG, EXTG_EN and EXTGX. The V_EXTG bit sets the gate drive voltage and can be set to 9V or 5V, for example. The EXTGX bits select which FET(s) to turn on. The EXTG_EN bit enables the gate driver to turn on the selected FET(s). The external FET can be turned on or off independently from other IC operation except when the IC is disabled. The EXT_EN_IND status bit set to 1 when external FET is enabled.

When a fault is detected and triggers a shutdown, the external FET may be turned off automatically. If EXT1 or EXT2 detects an OVP, then the respective FET would not turn on from off mode. The power train is enabled after all the registers have been initialized and the target input external FET is turned on. Sufficient time based on capacitance on the power path should be given between external FET on time to power train on time to minimize in-rush current. Next, both PT_EN pin and PT_EN bit are set to logic high (1) to turn on the power train. When either PT_EN pin or PT_EN pin is logic low, the power train is off In dual IC operation, the slave IC power train is turned on before the master IC. The COMP, SYNC and SYNCH pins from the two ICs gate the power train and synchronize the operation. SYNC_SEL pin sets the IC to master mode or slave mode. IC internal fault and programmable fault detection shuts down power train operation when a fault is detected.

In accordance with various embodiments, an example power converter initialization, an example power up sequence, and an example fault handling will now be described for the three different operating modes. In an example step-down regulation mode, the initialization and power up sequence uses EXT1 as an example. The same sequence may apply to EXT2 with the only change in EXTGX bit and related EXT2 register settings. First, pull EN to logic high and then set IC_EN bit=1 at 100 us (TBD) after EN is logic high to enable IC. IC startup from POR stage, POR bit reports 1 indicating fresh IC startup. Next, the POR bit is read to confirm the IC is enabled. The FREQUENCY register is then set to a desired setting. In dual IC operation, both ICs are set to the same frequency setting. The VOUT_REG register is set to the target regulation voltage on the VOUT sense pin in CV operation. The VBATT_REG register is set to the target regulation voltage on the VBATTP sense pin in CV operation. The IOUT_MAX register is set to the target maximum charger current in CC operation, and the IIN_MAX register is set to a value below the adapter current limit. Next, the FAULT and WARNING registers was set to a desired setting. Each Fault and Warning enables at a different time based on IC status and operating mode. The WATCHDOG register is then set to a desired setting.

The MODE register and other related registers are set for step-down regulation mode, including power train setup and enablement of an external FET, while checking for faults. In a dual IC operation, the external FETs are controlled by the master IC. If a fault (e.g., OVP event) is detected, then a shutdown register may be set to “1” to indicate a fault shutdown event and a sequence to enable the external FET after the shutdown fault is initiated. Next, the power train is enabled. In a dual IC operation, the slave IC power train is turned on before the master IC. After the power train is enabled, a bit may be set to indicate that the power train is ready and charging the battery. In some embodiments, a watchdog timer may be set to periodically check the IC status during charging operation.

If a fault event is detected, then the IC determines which faults events were triggered, such as the power train may be set to enable but it is off due to fault(s), an external FET is set to enable but the FET is off due to fault(s). The shutdown procedure may include resetting register values and repeating setup steps of enabling the power train, external FET, or other component that is disabled due to a fault.

An example step-down divide-by-3 power converter mode initialization and power up sequence will now be described. The initialization and power up sequence uses EXT1 as an example, but it will be appreciated that the same sequence applies to EXT2 with a change in EXTGX bit and related EXT2 register settings. The EN is pulled to logic high and then IC_EN bit=1 at 100 us (TBD) after EN is logic high to enable IC. The IC starts up from POR stage, POR bit reports 1 indicating fresh IC startup. The POR bit is read to confirm the IC is enabled. The FREQUENCY register is set to a desired setting. In dual IC operation, both ICs are set to the same frequency setting. The IIN_MAX register is set to a value below the adapter current limit. VOUT_REG, VBATT_REG and IOUT_MAX registers are not used in step-down divide-by-3 charge pump mode. Voltage and current regulation in step-down divide-by-3 charge pump mode may be controlled by the PPS adapter. The FAULT, WARNING, and WATCHDOG registers are set to desired settings. Each Fault and Warning enables at different time based on IC status and operating mode.

The MODE register and other registers are set for step-down divide-by-three mode, including power train setup and external FET setup, while checking for faults. If a fault (e.g., OVP event) is detected, then a shutdown register may be set to “1” to indicate a fault shutdown event and a sequence to enable the power train or external FET, as appropriate, after the shutdown fault is initiated. Next, the power train is enabled. After the power train is enabled, a bit may be set to indicate that the power train is ready and charging the battery. In some embodiments, a watchdog timer may be set to periodically check the IC status during charging operation. Voltage and current regulation in step-down divide-by-3 charge pump mode may be controlled by the PPS adapter.

If a fault event is detected, then the IC determines which faults events were triggered, such as the power train may be set to enable but it is off due to fault(s), or an external FET is set to enable but the FET is off due to fault(s). The shutdown procedure may include resetting register values and repeating setup steps of enabling the power train, external FET, or other component that is disabled due to a fault.

An example reverse step-up mode initialization and power up sequence will now be described. This initialization and power up sequence uses EXT2 as an example, but the same sequence applies to EXT1 with the change in EXTGX bit and related EXT1 register setting. The value EN is pulled to logic high and then IC_EN bit is set to 1 at 100 us (TBD) after EN is logic high to enable IC. The IC starts up from the POR stage, and the POR bit reports 1 indicating a fresh IC startup. The POR bit is read to confirm the IC is enabled. Next, the FREQUENCY register is set to a desired setting. In dual IC operation, both ICs are set to the same frequency setting. The VOUT_REG register is set to the target regulation voltage at VIN. Next, the IIN_MAX register is set to the target current limit. VBATT_REG and IOUT_MAX registers are not used in reverse step-up mode. FAULT, WARNING, and WATCHDOG registers are set to desired settings. Each Fault and Warning enables at a different time based on IC status and operating mode.

The MODE register and other registers are set for reverse step-up mode, including power train setup and external FET setup, while checking for faults. If a fault (e.g., OVP event) is detected, then a shutdown register may be set to “1” to indicate a fault shutdown event and a sequence to enable the power train or external FET, as appropriate, after the shutdown fault is initiated. Next, the power train is enabled. After the power train is enabled, a bit may be set to indicate that the power train is ready and charging the battery. In some embodiments, a watchdog timer may be set to periodically check the IC status during charging operation. Voltage and current regulation in step-down divide-by-3 charge pump mode may be controlled by the PPS adapter. In dual IC operation, the slave IC power train is turned on before the master IC and is controlled by the master IC.

If a fault event is detected, then the IC determines which faults events were triggered, such as the power train may be set to enable but it is off due to fault(s), or an external FET is set to enable but the FET is off due to fault(s). The shutdown procedure may include resetting register values and repeating setup steps of enabling the power train, external FET, or other component that is disabled due to a fault. The EXT2 or VIN pins are not configured to detect OVP as it is set as the output in reverse step-up mode. But if EXT2 or VIN pin detects an OVP event, then IC_STATUS1 and IC_STATUS2 would report the fault event.

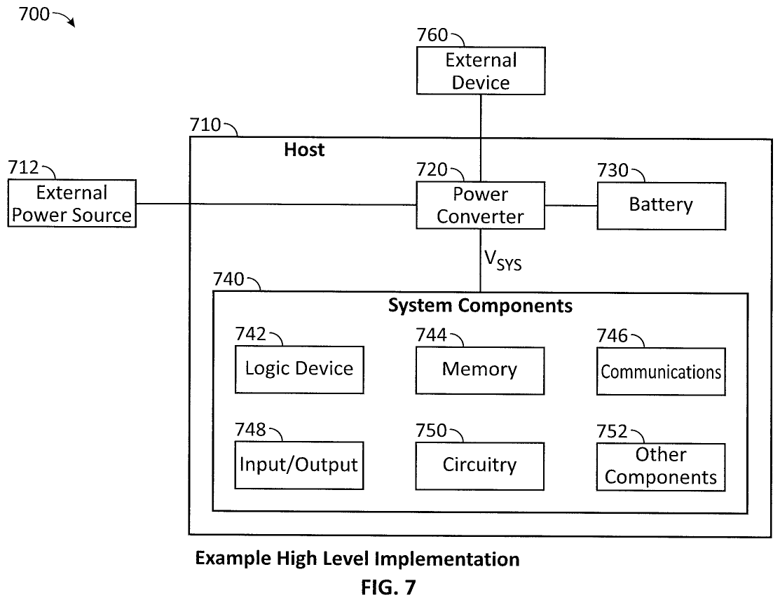

In an example system 700 illustrated in FIG. 7, a power converter 720 is implemented in a host 710 (e.g., a device or system) that includes a battery 730 and various system components 740. The host 710 may be any system or device that implements a power converter as described herein, including but not limited to a smart phone, tablet, portable electronics, a mobile device, low power electronics, and other electronic systems. The battery 730 may include one or more batteries that store electricity for use by the host 710, such as single cell Li-ion and Li-polymer batteries.

The power converter 720 may be configured to convert electricity stored in the battery 730 to a desired system voltage, Vsys, for powering various system components 740, which may include one or more logic devices 742, memories 744, communications components 746, input/output (I/O) components 748, circuitry 750, and other components 752. The power converter 720 may also supply power to one or more external devices 760, such as a component connected to the host 710 through a wired or wireless connection, such as a USB compatible device. The power converter 720 may also be configured to receive power from an external power source 712 and convert the received power to the battery 730 for storage, or to the system components 740 and/or external device 760, as applicable.

In various embodiments, the one or more logic devices 742 and memories 744 may be configured to perform operations of the host 710. A logic device 742 may be implemented as a general-purpose processor, a digital signal processor (DSP), an application-specific integrated circuit (ASIC), a microcontroller, a programmable logic device (PLD), a field-programmable gate array (FPGA), or other programmable logic device(s). The logic device 742 and other components may be configured through hardwiring, software execution, or a combination of both. In various embodiments, the host 710 includes one or more memory devices designed to retain data, such as software instructions for execution by the logic device. The memory may include volatile and non-volatile memories, such as random-access memory (RAM), dynamic RAM (DRAM), static RAM (SRAM), non-volatile random-access memory (NVRAM), read-only memory (ROM), programmable read-only memory (PROM), erasable programmable read-only memory (EPROM), electrically-erasable programmable read-only memory (EEPROM), flash memory, hard disk drives, or other memory types. The logic device may be configured to execute software instructions residing in the memory, thereby accomplishing method steps and operations.

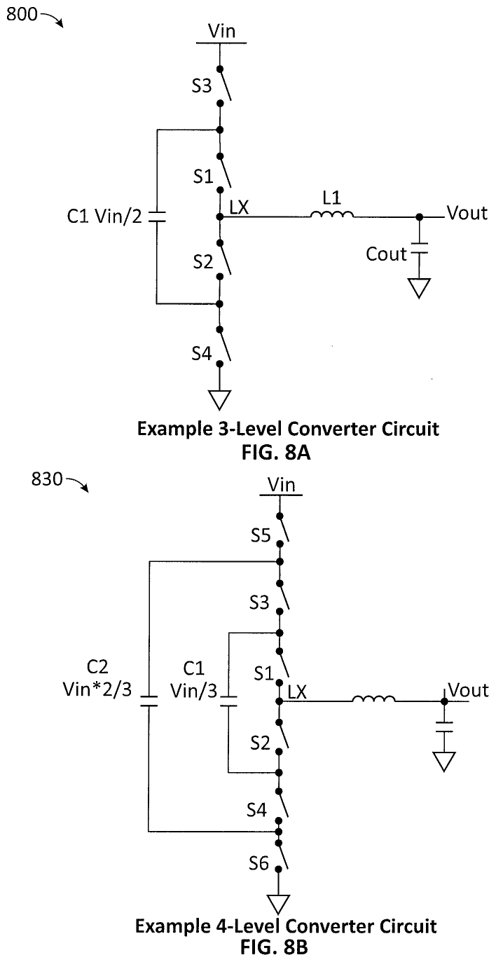

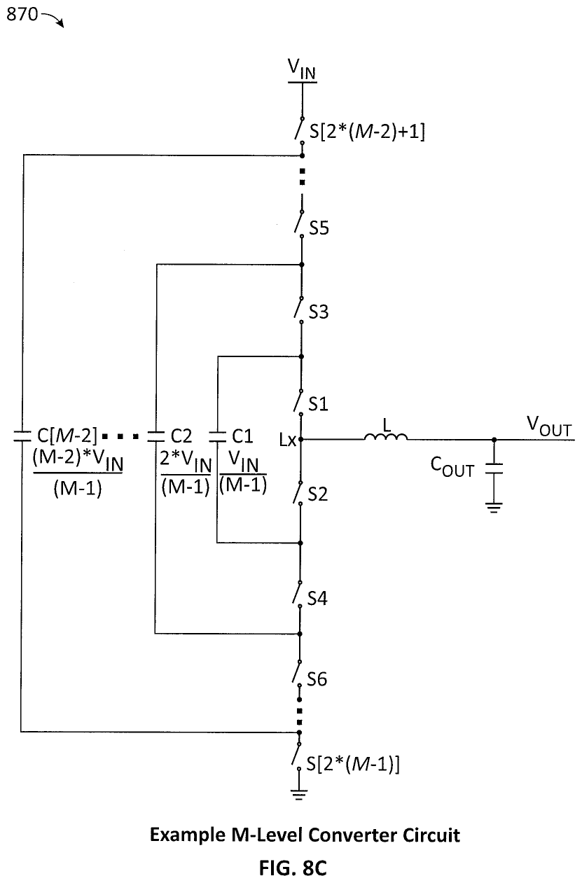

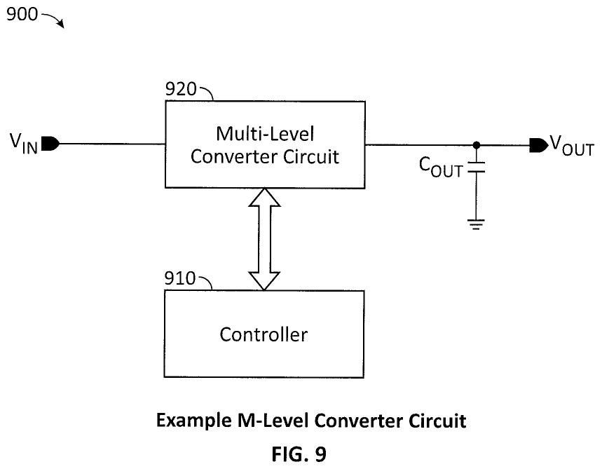

Referring to FIGS. 8A-8C, the converter circuit may be configured to switch between two or more switch states. One or more PWM duty cycle controllers may be provided to set the time in each switch state based on the voltage at VOUT. For example, FIG. 8A is a schematic diagram of a 3-level DC-to-DC buck converter circuit 800 that may be used as the converter circuit 920 of FIG. 9. A set of four switches, S1-S4, is series-coupled between VIN and circuit ground. A fly capacitor C1 is coupled in series with switches S3 and S4, and in parallel with switches S1 and S2. An inductor L1 is coupled to an output capacitor COUT and to a node LX between switches S1 and S2, and the voltage across the output capacitor COUT is VOUT.

In the illustrated example, the presence of the single fly capacitor C1 in the converter circuit 800 enables four switch states that each generate one of three voltage levels at node LX. In a first switch state, S2 and S4 are closed and S1 and S3 are open, effectively bypassing C1 and connecting LX to circuit ground (voltage level at LX=GND). In a second switch state, S2 and S4 are open and S1 and S3 are closed, effectively bypassing C1 and connecting LX to VIN (voltage level at LX=VIN). In a third switch state S1 and S4 are open and S2 and S3 are closed, connecting C1 from VIN to LX, and thus charging C1 with inductor L1 current flowing into a load. The voltage across C1 will be about VIN/2 and the voltage level at LX will also equal about VIN/2. In a fourth switch state, S1 and S4 are closed and S2 and S3 are open, connecting C1 from LX to GND and thus discharging C1 with inductor L1 current flowing to a load. The voltage across C1 will be about VIN/2 and the voltage level at LX will also equal about VIN/2 (e.g., this may assume that C1 was previously charged in state three). Accordingly, the illustrated converter circuit 800 has two switch states that generate a voltage level of VIN/2 at the LX node.

If the converter circuit 800 is toggled between switch states three and four (avoiding switch state two that bypasses the fly capacitor C1), the inductor L1 sees small jumps in the voltage level at LX, going from GND to only VIN/2 and back to GND, which results in reduced voltage ripple across the inductor L1 and less filtering to smooth VOUT than a converter circuit with only S1 and S2 switches.

Adding additional series switches Sx and fly capacitors Cx to the 2-level converter circuit 800 increases the number of switch states and resulting voltage levels between VIN and circuit ground that can be applied to the LX node, thus generating an even smaller voltage ripple across the inductor L. This reduces the filtering requirements to get a smooth output voltage. For example, a 4-level DC-to-DC buck converter circuit (see, e.g., FIG. 8B) includes 6 series-coupled switches S1-S6 and two fly capacitors Cx (X=2). Consequently, a 4-level converter circuit can define 4 voltage levels (VIN, GND, ⅓VIN, and ⅔VIN) at node LX from 8 switch states (3 switch states result in the ⅓VIN level at LX, and 3 other switch states result in the ⅔VIN level at LX). For some applications, VOUT is set low enough that the voltage level at node LX alternates between GND and the next higher voltage level available. For higher output voltages, the switching pattern may never use GND. For example, in a 4-level converter circuit, an output VOUT set to 0.5*VIN can be achieved by alternating the LX node between ⅔ VIN and ⅓ V.

A different interpretation of a multi-level converter circuit is that the fly capacitors Cx create a charge-pump for the buck converter circuit. Unlike a standard charge-pump where the output is restricted to one output, a multi-level converter circuit allows the fly capacitors Cx to be coupled to create multiple intermediate voltages. For the 4-level example, the two fly capacitors each act as a ⅓ charge-pump with the additional benefit that any input voltage that is a sum of ⅓ ratios can be created, including VIN and GND.

A multi-level converter circuit couples the fly capacitors Cx in different combinations in order to bring the voltage level at the LX node down or up. As noted above, when a fly capacitor is used (i.e., not bypassed), the electrical energy flowing through that fly capacitor generally will either charge it or discharge it, which creates a control problem in maintaining an average voltage.

Resolving the charge-balance problem so as to maintain an average voltage across the single capacitor in a 3-level converter circuit will now be described. For example, in a 3-level converter circuit, one way to generate the Level-1 (GND) and Level-3 (VIN) voltage levels at the LX node is to not use the fly capacitors C1 for these LX voltage levels. However, for the Level 2 (VIN/2) voltage level at LX, two separate switch states can be used: one switch state charges the capacitor (S3 and S2 closed, S1 and S4 open) and the other switch state discharges the capacitor (S3 and S2 open, S1 and S4 closed). The control of a 3-level converter circuit may operate such that each time the converter circuit switches states to Level-2, a controller can alternate between charging and discharging the single capacitor to maintain its voltage. A voltage comparator can be used to monitor the capacitor to help decide on a charging state or a discharging state. For instance, if the capacitor voltage is below VIN/2, then a controller would select charge (the third switch state), and if the capacitor voltage is above VIN/2, then the controller would select discharge (the fourth switch state).

Referring to FIGS. 8B, a 4-level converter circuit 830 (X=2) illustrates the charge-balance difficulty when more capacitors are present. A Level-1 voltage level (GND) and a Level-4 voltage level (VIN) at the LX node are each determined by a single switch state. However, the Level-2 voltage level (⅓ VIN) and Level-3 voltage level (⅔ VIN) at LX each can be achieved by any of three different switch states. At higher orders of a multi-level converter circuit (X>2), more switch states are possible for generating the intermediate levels between VIN and GND. The problem gets more complicated with a 5-level converter circuit (X=3). A Level-1 voltage level (GND) and a Level-5 voltage level (VIN) at the LX node are each determined by a single switch state. However, the Level-2 voltage level (¼VIN) and Level-4 voltage level (¾ VIN) at LX each can be achieved by any of four different switch states, the Level-3 voltage level (2/4 VIN) at LX can be achieved by any of six different switch states.

As should be clear from these examples, determining a suitable charge-balance method can become exceedingly difficult as the complexity of a multi-level converter circuit increases. As previously noted, most conventional control methods rely on establishing a sequence of linked state-changes to try to achieve charge balance. Control systems based on long sequences of switch states generally assume that all system variables—such as input voltage and output current—are constant during the sequence. This is unrealistic for a real-world environment, where all system variables tend to be dynamic.

In a 2-Level example, the converter circuit switches between two switch states: S1 closed and S2 open (voltage level at L_{X}=V_{IN}), or S1 open and S2 closed (voltage level at L_{X}=GND). A PWM duty cycle controller sets the time in each switch state based on the voltage at VOUT, which determines the amplitude of the average voltage at L_{X} (noting that, the average L_{X} voltage in theory is equal to the V_{OUT} average voltage, but that, due to parasitics, the L_{X} average voltage is higher and/or lower (for negative currents) than the V_{OUT} average). As can be appreciated, the inductor L sees large jumps in the voltage level at L_{X}, from GND to V_{IN} and back to GND. The resulting voltage ripple across the inductor L necessitates a significant amount of filtering to smooth VOUT.

An alternative way of reducing the voltage ripple across the inductor L is to add more series switches as well as charge transfer capacitors as energy storage elements to transfer charge from VIN to VOUT. As noted above, such charge transfer capacitors are commonly known as “fly capacitors” or “pump capacitors” and may be external components coupled to an integrated circuit embodiment of a converter circuit. The presence of X fly capacitors Cx defines a multi-level capacitive converter circuit capable of generating M=X+2 voltage levels at node L_{X} from 2^{(X*1)} switch states.

FIG. 8C is schematic diagram of a generalized M-level multi-level converter cell 870 that may be used as the converter circuit 920 of FIG. 9. A set of switches, S1-S[2*(M−1)], is series-coupled between VIN and circuit ground. The set of switches are organized in switch pairs: S1 & S2, S3 & S4, . . . S[2*(M−2)+1]& S[2*(M−1)]. A set of M−2 fly capacitor Cx is coupled in series with certain respective switches, and in parallel with switches in between those switches. In terms of switch pairs, there are M−1 pairs of switches, or one more than the number of fly capacitors. An optional inductor L is coupled to an output capacitor CO_{UT} and to a node L_{X} between switches S1 and S2, and again the voltage across the output capacitor C_{OUT} is V_{OUT}. The inductor L doubles as a virtual current source that facilitates movement of charge between the fly capacitors Cx. This creates a very efficient form of charge transfer, but introduces the problem of charge-balancing the fly capacitors Cx.

In various embodiments, each fly capacitor Cx has a first terminal coupled between an outer high-side switch S[2*x+1] and an inner high-side switch S[2*x−1], where “high-side” refers to the VIN side of the converter circuit. Each fly capacitor Cx has a second terminal coupled between an outer low-side switch S[2*x+2] and an inner low-side switch S[2*x], where “low-side” refers to the circuit ground (GND) side of the converter circuit. Thus, for an M=3 multi-level converter cell, a first terminal of the single (X=1) fly capacitor C1 would be coupled between outer high-side switch S3 and inner high-side switch S1, and a second terminal of the capacitor C1 would be coupled between inner low-side switch S2 and outer low-side switch S4. Accordingly, each fly capacitor Cx within the multi-level converter cell 870 has four switches that can affect current flow through that fly capacitor Cx.

In some embodiments, a voltage detector, which may be a simple comparator-type circuit, is provided to sense the voltage across a corresponding fly capacitor Cx with respect to a reference voltage, VREF, which represents a desired target voltage for the fly capacitor Cx. Every fly capacitor Cx may have a target average voltage in order to maintain proper output level. For an M-level converter and capacitor Cx, where x=1, 2, . . . [M−2], its target voltage is:

$$Vtarget [ Cx ] = {V}_{IN} * \frac{x}{M - 1}$$

The voltage detector may be configured to output a HIGH/LOW status signal, C_{Fx_H/L}, indicating with the voltage across the corresponding fly capacitor Cx is greater than V_{REF} or less than V_{REF}. The C_{Fx_H/L} status signal is coupled to control circuitry for the switches associated with the fly capacitor Cx.

The control circuitry for the four switches that can affect current flow through a fly capacitor Cx set states for those switches in part as a function of the voltage across the fly capacitor Cx as measured by the associated voltage detector and conveyed by the C_{Fx_H/L}x status signal. Accordingly, for ease of understanding, it can be said that each fly capacitor Cx “controls” its own pairs of high-side and low-side switches. If it is assumed that current flow in the inductor is charging the output V_{OUT}, there are four possible states that can be defined for the pairs of high-side and low-side switches for each fly capacitor Cx.

In a switch state in which the outer high-side and inner low-side switches associated with fly capacitor Cx are closed and all other associated switches are open, fly capacitor Cx would be in a charging configuration (whether or not charging actually occurs may depend on the switch states for other fly capacitors Cx). In a switch state in which the inner high-side and outer low-side switches associated with fly capacitor Cx are closed and all other associated switches are open, fly capacitor Cx would be in a discharging configuration (whether or not discharging actually occurs may depend on the switch states for other fly capacitors Cx). In a switching state in which the inner low-side and outer low-side switches associated with fly capacitor Cx are closed and all other associated switches are open, fly capacitor Cx would be bypassed. In a switching state in which the outer high-side and inner high-side switches associated with fly capacitor Cx are closed and all other associated switches are open, fly capacitor Cx would again be bypassed.

While each fly capacitor Cx can control both of its own pairs of high-side and low-side switches, in general, methods of control disclosed herein may utilize either the outer switches or the inner switches controllable by each corresponding capacitor. For example, referring to FIG. 8B, in “outer-switch” methods, fly capacitor C1 will control its outer switches S3 and S4, fly capacitor C2 will control its outer switches S5 and S6, etc. Conversely, for example, in “inner-switch” methods, fly capacitor C1 will control its inner switches S1 and S2, fly capacitor C2 will control its inner switches S3 and S4, etc. The switch states of either pair (inner or outer) of switches controlled by a fly capacitor Cx may be complementary—that is, no fly capacitor Cx closes or opens both of its high-side and low-side controlled switches at the same time. If each fly capacitor Cx controls its outer-switches, then no fly capacitor controls the left-over innermost switches S1 and S2. If instead each fly capacitor Cx controls its inner-switches, then no fly capacitor controls the left-over outermost switches S[2*(M−1)] and S[2*(M−2)+1]. Switch states for the left-over switches are also complementary.

FIG. 9 is a high-level block diagram of an example circuit that includes a power converter 900, in accordance with one or more embodiments of the present disclosure. In the illustrated example, the power converter 900 includes a converter circuit 920 and a controller 910. The converter circuit 920 and controller 910 may be configured to implement, for example, any of the multi-level power converter circuits as previously described with reference to FIGS. 1A-8C, and as described further herein. In the illustrated embodiment, the converter circuit 920 is configured to receive an input voltage VIN from a voltage source and transform the input voltage VIN into an output voltage V_{OUT}. In some embodiments of the power converter 900, auxiliary circuitry (not shown), such as a bias voltage generator(s), a clock generator, a voltage control circuit, etc., may also be present and coupled to the converter circuit 920 and the controller 910.

The controller 910 receives a set of input signals and produces a set of output signals. Some of these input signals arrive along a signal path connected to the converter circuit 920. These input signals carry information that is indicative of the operational state of the converter circuit 920. The controller 910 may also receive a clock signal CLK (for synchronous converter circuits 920) and one or more external input/output signals I/O that may be analog, digital (encoded or direct signal lines), or a combination of both. Based upon the received input signals, the controller 910 produces a set of control signals back to the converter circuit 920 that control the internal components of the converter circuit 920 (e.g., internal switches, such as low voltage FETs/MOSFETs) to cause the converter circuit 920 to boost or buck VIN to V_{OUT}. In some embodiments, an auxiliary circuit (not shown) may provide various signals to the controller 910 (and optionally directly to the converter circuit 920), such as the clock signal CLK, the input/output signals I/O, as well as various voltages, such as a general supply voltage VDD and a transistor bias voltage VBIAS.

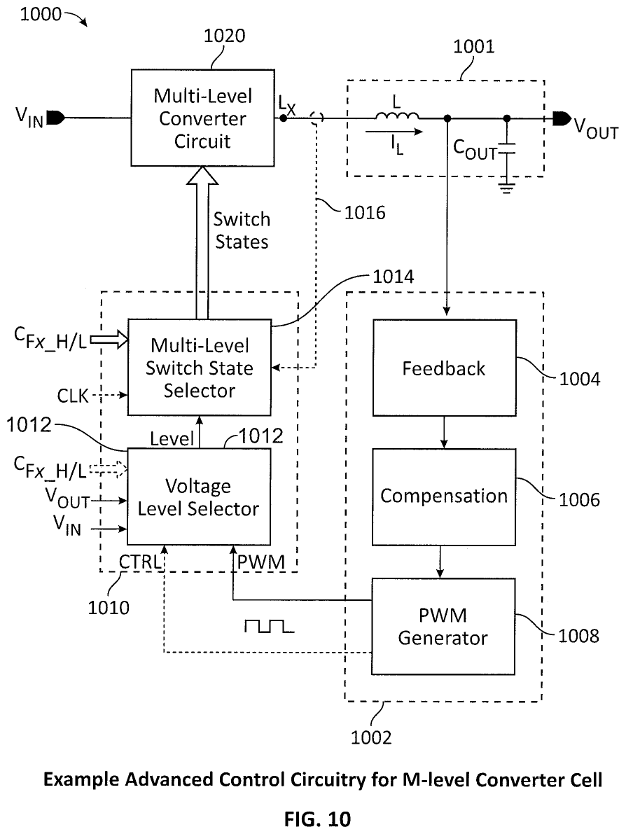

FIG. 10 is a block diagram of one embodiment of advanced control circuitry 1000 for an M-level converter cell 1000 such as the generalized version depicted in FIG. 8B. The M-level converter cell 1020 is shown coupled to an output block 1001 comprising an inductor L and an output capacitor C_{OUT} (conceptually, the inductor L also may be considered as being included within the M-level converter cell 1020). The advanced control circuitry 1000 functions as a control loop coupled to the output of the M-level converter cell 1020 and to switch control inputs of the M-level converter cell 1020. In general, the advanced control circuitry 1000 is configured to monitor the output (e.g., voltage and/or current) of the M-level converter cell 1020 and dynamically generate a set of switch control inputs to the M-level converter cell 1020 that attempt to stabilize the output voltage and/or current at specified values, taking into account variations of VN and output load. In alternative embodiments, the advanced control circuitry 1000 may be configured to monitor the input of the M-level converter cell 1020 (e.g., voltage and/or current) and/or an internal node of the M-level converter cell 1020 (e.g., the voltage across one or more fly capacitors or the current through one or more power switches). Accordingly, most generally, the advanced control circuitry 1000 may be configured to monitor the voltage and/or current of a node (e.g., input terminal, internal node, or output terminal) of the M-level converter cell 1020. The advanced control circuitry 1000 may be incorporated into, or separate from, the overall controller for a power converter 100 embodying the M-level converter cell 1020.

A first block comprises a feedback controller 1002, which may be a traditional controller such as a fixed frequency voltage mode or current mode controller, a constant-ON-time controller, a hysteretic controller, or any other variant. The feedback controller 1002 is shown as being coupled to V_{OUT} from the M-level converter cell 1020. In alternative embodiments, the feedback controller 1002 may be configured to monitor the input of the M-level converter cell 1020 and/or an internal node of the M-level converter cell 1020. The feedback controller 1002 produces a signal directly or indirectly indicative of the voltage at V_{OUT} that determines in general terms what needs to be done in the multi-level converter cell 1020 to maintain desired values for V_{OUT}: charge, discharge, or tri-state (i.e., open, with no current flow).

In the illustrated example, the feedback controller 1002 includes a feedback circuit 1004, a compensation circuit 1006, and a PWM generator 1008. The feedback circuit 1004 may include, for example, a feedback-loop voltage detector which compares V_{OUT} (or an attenuated version of V_{OUT}) to a reference voltage which represents a desired V_{OUT} target voltage (which may be dynamic) and outputs a control signal to indicate whether V_{OUT} is above or below the target voltage. The feedback-loop voltage detector may be implemented with a comparison device, such as an operational amplifier (op-amp) or transconductance amplifier (gm amplifier).

The compensation circuit 1006 is configured to stabilize the closed-loop response of the feedback controller 1002 by avoiding the unintentional creation of positive feedback, which may cause oscillation, and by controlling overshoot and ringing in the step response of the feedback controller 1002. The compensation circuit 1006 may be implemented in known manner, and may include LC and/or RC circuits.

The PWM generator 1008 generates the actual PWM control signal which ultimately sets the duty cycle of the switches of the multi-level converter cell 1020. In addition, in some embodiments, the PWM generator 1008 may pass on additional optional control signals CTRL indicating, for example, the magnitude of the difference between V_{OUT} and the reference voltage (thus indicating that some levels of the M-level converter cell 1020 should be bypassed to get to higher or lower levels), and the direction of that difference (e.g., whether V_{OUT} is greater than or less than the reference voltage). In other embodiments, the optional control signals CTRL can be derived from the output of the compensation circuit 1006, or from the output of the feedback circuit 1004, or from a separate comparator (not shown) coupled to, for example, V_{OUT}. One purpose of the optional control signals CTRL is for advanced control algorithms, when it may be beneficial to know how far away V_{OUT} is from a target output voltage, thus allowing faster charging of the inductor L if the V_{OUT} is severely under regulated.

A second block comprises a multi-level controller 1010, the primary function of which is to select the switch states that generate a desired V_{OUT} while maintaining a charge-balance state on the fly capacitors within the M-level converter cell 1020 every time an output voltage level is selected, regardless of what switch state or states were used in the past.

The multi-level controller 1010 includes a Voltage Level Selector 1012 which receives the PWM control signal and the additional control signals CTRL if available. In addition, the Voltage Level Selector 1012 may be coupled to V_{OUT} and/or V_{IN}, and, in some embodiments, to the HIGH/LOW status signals, C_{Fx_H/L}, from the voltage detectors coupled to corresponding fly capacitors Cx within the M-level converter cell 1020. A function of the Voltage Level Selector 1012 is to translate the received signals to an output voltage Target Level (e.g., on a cycle-by-cycle basis). The Voltage Level Selector 1012 typically will consider at least V_{OUT} and V_{IN} to determine which Target Level should charge or discharge the output of the M-level converter cell 1020 with a desired rate. For example, in a 6-level converter circuit, the available Target Levels are Level-1 (GND), Level-2 (1/5V_{IN}), Level-3 (2/5V_{IN}), Level-4 (3/5V_{IN}), Level-5 (4/5V_{IN}), and Level-6 (V_{IN}), which may be represented as a count value from 1-6 (or 0-5).

As an example, in a 4-Level converter circuit, if V_{IN}=12V and V_{OUT} nominally should be 3V, then the Voltage Level Selector 1012 may indicate that a Target Level of “2” can be selected, which results in a 1/3V_{IN} voltage level at L_{X} (i.e., 4V). The PWM control signal sets a duty cycle between that Target Level and another Target Level (e.g., GND) so that the average voltage level at L_{X} will be about 3V.

In general, for steady-state operations, the Target Level voltage closest to V_{OUT} that either charges or discharges the inductor L may be selected for simplicity of the selection algorithm. In general, for transient response, a Target Level that is higher (for charging) or lower (for discharging) than the closest Target Level may be selected to quickly charge or discharge the inductor L. The Voltage Level Selector 1012 may be implemented, for example, as a look-up table (LUT) or as comparison circuitry and combinatorial logic or more generalized processor circuitry. In some embodiments, the Voltage Level Selector 1012 can implement advanced methods (described below) that try to speed up charging or discharging based on additional factors, such as inductor voltage drop, load transients, the magnitude of output deviations, and/or external input signals from external sources. The output of the Voltage Level Selector 1012 may include duty cycle information (e.g., derived from the input PWM control signal) as well as switch state.

The output of the Voltage Level Selector 1012 is coupled to a Multi-Level Switch State Selector 1014, which generally would be coupled to the status signals, C_{Fx_H/L}, from the voltage detectors for the fly capacitors Cx. Taking into account the Target Level generated by the Voltage Level Selector 1012, the Multi-Level Switch State Selector 1014 determines a pattern of switch states for the desired output level that generally achieves charge-balancing the fly capacitors Cx. The Multi-Level Switch State Selector 1014 may be implemented, for example, as comparison circuitry and combinatorial logic, as a look-up table (LUT), or as more generalized processor circuitry. The output of the Multi-Level Switch State Selector 1014 is coupled to the switches of the multi-level converter cell 1020 (through appropriate level-shifter circuits and drivers circuits, as may be needed for a particular converter cell) and includes a pattern of switch state settings determined by the Multi-Level Switch State Selector 1014. The pattern of switch state settings selects the configuration of the switches within the multi-level converter cell 1020.

In general (but not always), for PWM-based control systems, the Voltage Level Selector 1012 and the M-level Switch State Selector 1014 only change their states when the PWM signal changes. For example, when the PWM signal goes high, the Voltage Level Selector 1012 selects which level results in charging of the inductor L and the M-level Switch State Selector 1014 sets which version to use of that level. Then when the PWM signal goes low, the Voltage Level Selector 1012 selects which level can discharge the inductor L and the M-level Switch State Selector 1014 sets which version of that level to use. Thus, the Voltage Level Selector 1012 and the M-level Switch State Selector 1014 generally only change states when the PWM signal changes (the PWM signal is in effect their clock signal). However, there may be situations or events where it is desirable for the CTRL signal to change the state of the Voltage Level Selector 1012. Further, there may be situations or events where it is desirable for the C_{Fx_H/L} status signal(s) to cause the M-level Switch State Selector 1014 to select a particular configuration of power switch settings, such as when a severe mid-cycle imbalance occurs. In some embodiments, it may be useful to include a timing function that forces the M-level Switch State Selector 1014 to re-evaluate the optimal version of the state periodically, for example, in order to avoid being “stuck” at one level for a very long time, potentially causing charge imbalances.

One notable benefit of the control circuitry shown in FIG. 10 is that it enables generation of voltages in boundary zones between voltage levels, which represent unattainable output voltages for conventional multi-level DC-to-DC converter circuits.

In alternative unregulated charge-pumps embodiments, the feedback controller 1002 and the Voltage Level Selector 1012 may be omitted, and instead a clock signal CLK may be applied to the M-level Switch State Selector 1014. The M-level Switch State Selector 1014 would generate a pattern of switch state settings that periodically charge balances the fly capacitors Cx regardless of what switch state or states were used in the past (as opposed to cycling through a pre-defined sequency of states). This ensures that if V_{IN} changes or anomalous evens occur, the system generally always seeks charge balance for the fly capacitors Cx.

In some embodiments, the M-level Switch State Selector 1014 may take into account the current I_{L} flowing through the inductor L by way of an optional current-measurement input 1016, which may be implemented in conventional fashion.

In an M-level multi-level converter circuit, the configuration of switches that achieves Level-1 (e.g., GND) or Level-M (e.g., V_{IN}) effectively bypasses the fly capacitors Cx. Conversely, for all intermediate voltage levels, at least one fly capacitor Cx is coupled to V_{OUT} and there are always at least two configurations of switches that can achieve any intermediate voltage level. For any particular intermediate voltage level, at least one configuration of switches results in charging the associated fly capacitor and at least one other configuration of switches results in discharging the associated fly capacitor. One aspect of the present disclosure is the realization that any achievable output voltage V_{OUT} requiring intermediate voltage levels can be attained by dynamically selecting patterns of switch configurations—that is, by selecting switch configurations without regard to or memory of the switch configurations of any previous switching cycle—to select appropriate Levels, and doing so in a way that purposefully selects either charging or discharging switch configurations that also balance charge across the fly capacitors Cx.

Embodiments of the disclosure use the following approach for positive inductor L current (charging V_{OUT}):
(1) a fly capacitor Cx that needs charging will be set to close its charging switch (the outer high-side switch in outer-switch control methods, or the inner low-side switch for inner-switch control methods); and
(2) a fly capacitor Cx that needs discharging will be set to close its discharging switch (the outer low-side switch for outer-switch control methods, or the inner high-side switch for inner-switch control methods).

For negative inductor L current (discharging V_{OUT}), the selection of switches inverts. Accordingly:
(1) a fly capacitor Cx that needs charging will be set to close its charging switch (the outer low-side switch in outer-switch control methods, or the inner high-side switch for inner-switch control methods); and
(2) a fly capacitor Cx that needs discharging will be set to close its discharging switch (the outer high-side switch for outer-switch control methods, or the inner low-side switch for inner-switch control methods).

Note again that whether or not charging actually occurs for a particular fly capacitor Cx generally depends on the switch states for all other fly capacitors. For a fly capacitor C(x) to actually charge or discharge, the next inward (if one exists) fly capacitor C(x−1) (for outer-switch control methods) or the previous outward (if one exists) fly capacitor C(x+1) (for inner-switch control methods) must be set to the opposite state (i.e., discharge or charge) so that a bypass situation does not occur.

For any multi-level converter circuit of order M that can create M voltage levels—i.e., Level-1 (e.g., GND) through Level-M (e.g., V_{IN})—then the following switch count rules apply for any Level-m:
(1) M−m low-side switches must be set to be closed (ON);
(2) m−1 high-side switches must be set to be closed (ON); and
(3) switches that are not required to be ON must be set to be OFF (open).

With these switch count rules in mind, the following generalized capacitor control method applies for each state change of the Multi-Level Switch State Selector 1014:
Step 1) Select a fly capacitor that has not previously been selected;
Step 2) If the voltage of the selected fly capacitor is above its Vtarget and there are remaining (i.e., not been set by this method in this cycle) low-side or high-side switches that can be set to be closed to enable a discharge path for the selected fly capacitor, then set those switches that enable a discharge path for the selected fly capacitor to be closed, decrement one or more appropriate counters (e.g., for the number of low-side switches set to be closed and the number of high-side switches set to be closed), and flag the current fly capacitor as “done” (i.e., as having been selected); otherwise (since the voltage of the selected fly capacitor is below its Vtarget) set the switches that enable a charging path for the selected fly capacitor to be closed and flag the current fly capacitor as “done”;
Step 3) Loop to Step 1 until all fly capacitors have been selected;
Step 4) For the remaining pair of left-over switches, set the high-side switch or the low-side switch to be closed based on the switch count rules and the counter values.

With the above generalized capacitor control method, more specific multi-level charge-balancing control methods can be created. Examples can be found, for example, in U.S. Patent Publication No. 20230148059, which is incorporated by reference herein in its entirety.

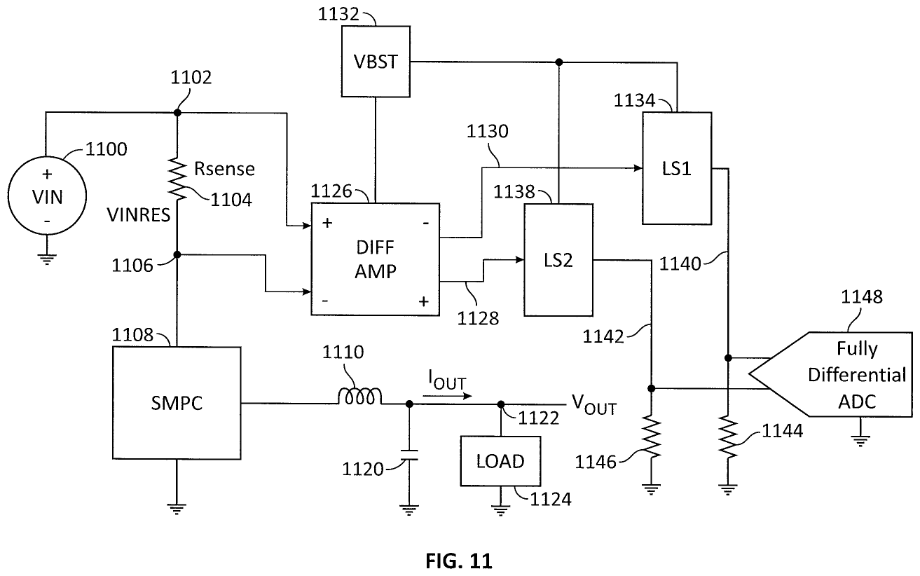

Referring now to FIG. 11, a switched mode power converter 1108 (SMPC) is shown receiving voltage and current from an input voltage source VIN 1100. Switched mode power converter 1108 may be a conventional buck converter or charge pump converter; it may also be a multi-level converter of the type described above in FIG. 8A through FIG. 10. As will be explained below, switched mode power converter 1108 may also be operated as a boost converter with minor modifications. Input voltage source VIN 1100 may be a wired power source, for example, a USB power voltage, but input voltage source VIN 1100 could also be a wireless power source, for example, voltage received by electromagnetic induction from a wireless transmitter. In the latter case, relatively large fluctuations in voltage may be present on input voltage source VIN 1100, creating a noisy operating environment. The output of SMPC 1108 is coupled by inductor 1110 to output node 1122. Filter capacitor 1120 extends between node 1122 and ground. Node 1122 provides an output voltage VOUT and output current IOUT for driving load 1124.

As shown in FIG. 11, a resistor 1104 is coupled between node 1102, which receives input voltage source VIN 1100, and node 1106, which supplies voltage and current to an input terminal of SMPC 1108. In some instances, it is desirable to track or monitor the input current IIN drawn by SMPC 1108. For example, it may be desired to ensure that the input current IIN being drawn by SMPC 1108 does not exceed a maximum threshold current. Another example is when it is desired to measure the input current IIN drawn by SMPC 1108 to estimate the output current IOUT being supplied to load 1124. If the value of resistor 1104 is known, then the voltage dropped across resistor 1104 can be measured and analyzed to determine the input current IIN. Resistor 1104 is a very low ohmic resistor to avoid significant power loss across the resistor. Resistor 1104 may either be fabricated on the same integrated circuit as has been described herein, or resistor 1104 may be an external resistor coupled to designated pins of the integrated circuit.

The voltage drop across resistor 1104 is relatively small; therefore, the voltage drop across resistor 1104 requires amplification, after which it may be sent to an analog-to-digital converter for accurate conversion, thereby providing a reading of the input current IIN.

Input voltage source VIN 1100 may vary widely, and may range between, for example, between approximately 4.5 V up to 18 V. Accordingly, the voltage signal developed across sensing resistor 1104, and hence, between nodes 1102 and 1106, will typically exist in an upper voltage domain proximate to the input voltage source VIN 1100. In theory, an analog to digital converter could be constructed to operate in this upper voltage domain for converting an amplified form of this voltage signal into a digital counterpart, and the digital counterpart could then be level shifted down to the lower voltage domain, but this approach would not make efficient use of available integrated circuit area. Analog to digital converters are typically operated in a lower voltage domain near ground potential (or other reference potential). Accordingly, it would be advantageous to shift an amplified version of the differential voltage across nodes 1102 and 1104 down to a corresponding voltage near ground potential (or other reference potential) before being presented to the analog to digital converter. In addition, due to the rather noisy operating environment in which switched mode power converter 1108 is operating, it would be advantageous to process the voltage developed across sensing resistor 1104 in a differential fashion; any noise on node 1102 (the input voltage source VIN 1100) will also be present on node 1106, and differential processing of the voltage developed across sensing resistor 1104 will cancel out noise introduced by input voltage source VIN 1100. While a differential architecture is therefore preferred, the design of such a differential architecture is not straightforward.

As shown in FIG. 11, the voltages on nodes 1102 and 1106 are supplied to the non-inverting and inverting input terminals of differential amplifier 1126. Differential amplifier 1126 amplifies the differential input voltage developed across sensing resistor 1104 and provides an amplified differential output voltage across a pair of output terminals coupled to non-inverting output line 1128 and inverting output line 1130. To save on integrated circuit die area, differential amplifier 1126 is preferably constructed from low voltage devices operated in a higher voltage domain. In a noisy operating environment, a generated voltage supply having a voltage that is somewhat higher, or somewhat lower, than input voltage source VIN may be provided in order to use low voltage components in the higher voltage domain to process the incoming differential input voltage. However, it should be noted that both the generated voltage supply and the input voltage source VIN will both be noisy.

Differential amplifier 1126 in FIG. 11 is coupled to generated voltage supply VBST (VBOOST) 1132. VBST box 1132 may be constructed, for example, as a charge pump powered by the VIN input voltage source, producing a nominal VBST voltage approximately 3-5 volts above VIN. The VIN input voltage source therefore has a voltage level located between the generated voltage supply VBST and ground potential. The design of charge pumps is well known to those skilled in the art, and details for constructing such a charge pump may be found in the technical article “Design of Charge Pump Circuit for PLL Application: A review”, by Deepshikha Mittal and Virendra Verma, published in International Journal of Engineering Research & Technology (IJERT), Vol. 4 Issue 05, May 2015, the contents of which are hereby incorporated by reference. In some instances, differential amplifier 1126 is designed to operate in the upper voltage domain, as between VIN and VBST.

Still referring to FIG. 11, the inverting output 1130 of differential amplifier 1126 is coupled to an input terminal of a first level shifting block LS1 1134. Similarly, the non-inverting output 1128 of differential amplifier 1126 is coupled to an input terminal of a second level shifting block LS2 1138. Both LS1 block 1134 and LS2 block 1138 are also coupled to the generated voltage supply VBST 1132. LS1 block 1134 includes an output terminal that outputs a current on line 1140 conducted by resistor 1144 to ground for producing a first ground-based output voltage on line 1140 related to the voltage on node 1102. Likewise, LS2 block 1138 includes an output terminal that outputs a current on line 1142 conducted by resistor 1146 to ground for producing a second ground-based output voltage on line 1142 related to the voltage on node 1106. The first ground-based output voltage on line 1140 and the second ground-based output voltage on line 1142 collectively correspond to a differential level-shifted output voltage relative to the reference potential in the lower voltage domain. The differential voltage presented on lines 1140 and 1142 is then provided to fully differential analog to digital converter block 1148 to create a digital representation of the input current IIN conducted through sensing resistor 1104 to SMPC 1108.

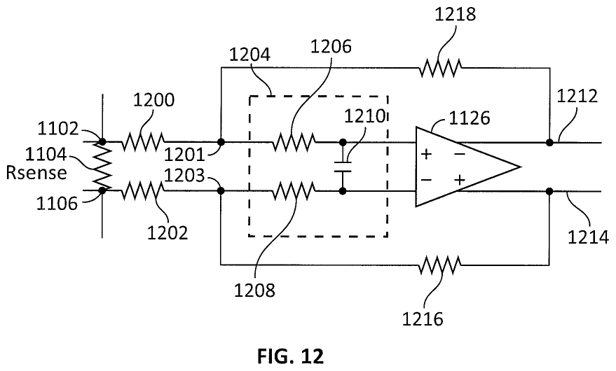

FIG. 12 provides additional details concerning differential amplifier 1126. Nodes 1102 and 1106, located on opposing sides of sensing resistor 1104, are repeated in FIG. 12. Node 1102 is coupled through a first input resistor 1200 to node 1201, and node 1104 is coupled through a second input resistor 1202 to node 1203. Input resistors 1200 and 102 have identical resistances and are both much greater than sensing resistor 1104. Nodes 1201 and 1203 are coupled through a filter block 1204 to the non-inverting and inverting input terminals, respectively, of differential amplifier 1126. Filter block 1204 is provided to improve immunity to noise. Within filter block 1204, resistor 1206 couples node 1201 to the non-inverting input terminal of differential amplifier 1126, and resistor 1208 couples node 1203 to the inverting input terminal of differential amplifier 1126. Filter block 1204 also includes a filter capacitor 1210 coupled between the non-inverting input terminal and the inverting input terminal of differential amplifier 1126. Differential amplifier 1126 is configured to provide a fixed gain, and may be of several different types known to those skilled in the art, including very low offset commutating amplifiers and very low offset chopping amplifiers.

Still referring to FIG. 12, the non-inverting output terminal of differential amplifier 1126 is coupled to line 1214, and is further coupled by a first feedback resistor 1216 back to node 1203. Likewise, the inverting output terminal of differential amplifier 1126 is coupled to line 1212, and is further coupled by a second feedback resistor 1218 back to node 1201; the resistance values of first feedback resistor 1216 and second feedback resistor 1218 are identical to each other. Amplifier 1126 has a very high open-loop gain on its own (perhaps 100 dB, or 100,000 times, or more). The feedback resistors 1218/1216 and input resistors 1200/1202 set a much lower gain (on the order of perhaps 30 times) which means any fluctuation in the open-loop gain of amplifier 1126 does not matter. The high open-loop gain of amplifier 1126 ensures a good linear closed-loop gain. The gain provided by differential amplifier 1126 is fixed by the ratio of the values of the feedback resistors (1216 and 1218) relative to the input resistors (1200 and 1202). The differential output voltage created by differential amplifier 1126 is equal to the differential input voltage dropped across sensing resistor 1104 multiplied by the ratio of Rfeedback/Rinput, wherein Rfeedback is the resistance value for feedback resistors 1216 and 1218, and Rinput is the resistance value for input resistors 1200 and 1202. Once again, the differential output voltage provided across lines 1212 and 1214 is in an upper voltage domain proximate to the voltage of VIN. Translating this differential output voltage to a lower voltage domain proximate to ground potential presents a challenge that will now be addressed.

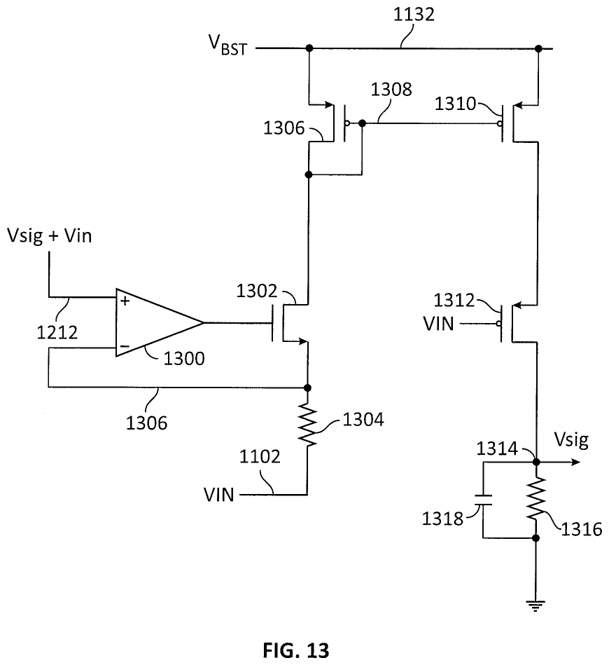

FIG. 13 sets forth a first embodiment of the circuitry included in first level shifter LS1 block 1134 of FIG. 11. It should be noted that the circuitry included within second level shifter LS2 block 1138 will be identical to that included in first level shifter LS1 block 1134. In FIG. 13, line 1212 (from FIG. 12) provides a voltage that is the voltage VIN plus a voltage Vsig equal to the voltage drop across the sensing resistor 1104 multiplied by the gain of differential amplifier 1126. In FIG. 13, line 1212 is shown being coupled to the non-inverting input terminal of a buffer amplifier 1300, which may be an operational amplifier. If desired, a low pole RC filter may be inserted on incoming line 1212, i.e., between the output 1130 of differential amplifier 1126 and the input to level shifter LS1 1134. Likewise, an identical low pole RC filter may be inserted between the output 1128 of differential amplifier 1126 and the input to level shifter LS2 1138. These low pole RC filters serve two main purposes. If amplifier 1126 is a chopping amplifier, then there is chopping noise at the output of differential amplifier 1126. The low pole RC filters serve to filter out such chopping noise, and they also help reduce any noise from the voltage supplies (VIN, VBST) to the level shifters LS1 and LS2. Buffer amplifier 1300 is configured to operate in the upper voltage domain, and to receive power from the generated VBST power supply. The amplified output of buffer amplifier 1300 is coupled to the gate of NMOS device 1302. The source of NMOS device 1302 is coupled by feedback line 1306 to the inverting input terminal of buffer amplifier 1300, and through resistor 1304 to input voltage VIN. In this manner, NMOS device 1302 is driven to conduct an amount of current through resistor 1304 sufficient to recreate the voltage Vsig above VIN as a feedback voltage on line 1306; in this regard, resistor 1304 may be regarded as a feedback resistor for generating such feedback voltage. The drain of NMOS device 1302 is coupled to both the gate and drain of PMOS device 1306. The source of PMOS device 1306 is coupled to the generated VBST voltage 1132. NMOS device 1302, resistor 1304 and PMOS device 1306 form a first current leg for conducting a current sufficient to create the voltage Vsig across resistor 1304 above VIN.

Still referring to FIG. 13, a second current leg includes PMOS device 1310, PMOS device 1312 and resistor 1316. The source of PMOS device 1310 is coupled to the generated VBST power supply 1132. The gate of PMOS device 1310 is coupled to the gate and drain of PMOS device 1306, and thus PMOS device 1310 is biased to conduct the same current being conducted by PMOS device 1306. The second leg (1310, 1312, 1316) thereby mirrors the current conducted by the first leg (1306, 1302, 1304). PMOS device 1312 has its gate coupled to the input voltage source VIN and passes the current conducted by PMOS device 1310 down to resistor 1316; it also establishes a voltage of VIN plus the gate-source threshold voltage of PMOS device 1312 at the drain of PMOS device 1310, which more closely matches the voltage at the drain of its mirrored partner, PMOS device 1306. Furthermore, PMOS device 1312 allows PMOS device 1310 to be a low voltage device, as the drain of PMOS device 1310 will not go below the voltage VIN plus the source-gate threshold voltage of PMOS device 1312. This ensures that PMOS device 1306 and PMOS device 1310 can be identical low voltage devices. While two identical high voltage devices could have been used to form PMOS devices 1306 and 1310, and perhaps thereby eliminate the need for PMOS device 1312, such high voltage devices would require more voltage to operate and much more chip area. It will be noted that PMOS device 1312 is a higher voltage device capable of operating over a wider voltage range. Noise from the VBST power supply will be somewhat common across the PMOS mirror devices 1306 and 1310 (which have matching Vgs voltages), thereby maintaining high noise immunity, even though the capacitances of PMOS device 1306 and PMOS device 1310 are not identical. In this embodiment, to provide sufficient immunity to noise, Vsig should be as large as possible, and balanced on a common mode. As a result, the generated power supply voltage VBST should be at least the maximum signal swing (about 2.5 volts) plus Vgs PMOS plus Vds NMOS, or at least 3.75 volts above VIN.

Resistor 1316 in FIG. 13 is selected to be of the same resistance value, and made from the same material in the same manner, as resistor 1304 so that resistors 1304 and 1316 track with each other over any process variations. Accordingly, since resistors 1316 and 1304 are identical, and since they conduct identical currents, the voltage Vsig created across resistor 1304 in the upper voltage domain will be reproduced across resistor 1316, at node 1314, relative to ground potential in the lower voltage domain. Capacitor 1318 is provided to help provide noise immunity. Thus, the first current leg (1302, 1304, 1306) and the second current leg (1310, 1312) form a current mirror that provides an output current to resistor 1316 related to the Vsig voltage. In FIG. 13, buffer amplifier 1300 will work to ensure that its input terminals are at the same voltage through negative feedback. This is achieved in the first leg (formed by PMOS device 1306, NMOS device 1302 and resistor 1304) where the diode-connected PMOS device 1306 will conduct just enough current to develop a voltage drop across resistor 1304 equal to the Vsig voltage. Hence if buffer amplifier 1300 is ideal, the current in resistor 1306 exactly matches the current in resistor 1304. To the extent that any gain error is introduced by the PMOS mirror formed by PMOS devices 1306 and 1310, such error can be eliminated by trimming resistors 1304 and 1316, or such error can be compensated when processing the digital representation of the input current produced by the analog to digital converter 1148. The two primary sources of error are: 1) buffer amplifier 1300 offset error (which means that nodes 1306 and 1314 will always have a fixed offset, e.g., a constant +5 mV error); and 2) gain error caused by any mismatch between resistors 1304 and 1316. Both of these sources of error can be trimmed or eliminated digitally via ADC 1148.

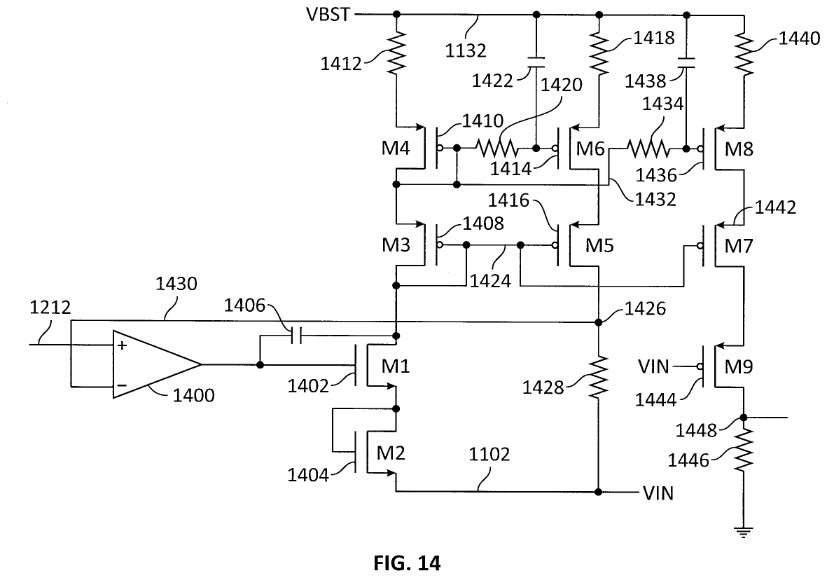

FIG. 14 shows a second embodiment of the circuitry included in the first level shifter LS1 block 1134 of FIG. 11. It should again be noted that the circuitry included within second level shifter LS2 block 1138 will be identical to that included in first level shifter LS1 block 1134. To improve matching between first level shifter LS1 block 1134 and second level shifter LS2 block 1138, they can be placed on the integrated circuit side-by-side or interleaved. In FIG. 14, line 1212 (from FIG. 12) again provides a voltage that is the voltage V_{IN} plus a voltage Vsig equal to the voltage drop across the sensing resistor 1104 multiplied by the gain of differential amplifier 1126. Line 1212 is coupled to the non-inverting input terminal of buffer amplifier 1400, which may be an operational amplifier. Buffer amplifier 1400 is configured to operate in the upper voltage domain, and to receive power from the generated VBST power supply. The amplified output of buffer amplifier 1400 is coupled to the gate of NMOS device 1402. Capacitor 1406 extends across the gate and drain of NMOS device 1402 and serves as a Miller compensation capacitor for loop stability purposes. The source of NMOS device 1402 is coupled to the drain and gate of NMOS device 1404, and the source of NMOS device 1404 is coupled to input voltage source VIN (node 1102). The drain of NMOS device 1406 is coupled to the gate and drain of PMOS cascode device 1408. The source of PMOS device 1408 is coupled to the gate and drain of PMOS device 1410, and the source of PMOS device 1410 is coupled through resistor 1412 to the generated VBST power supply 1132. Thus, devices 1402, 1404, 1408, 1410, and resistor 1412 form a first current leg between the generated VBST power supply and input voltage VIN.

Still referring to FIG. 14, a second current leg is formed between the generated VBST power supply and input voltage VIN by resistor 1418, PMOS device 1414, PMOS cascode device 1416, and resistor 1428. Resistors 1412, 1418, and 1428 are all selected to have the same resistance value. The gate of PMOS device 1414 is coupled to the gate of PMOS device 1410 by an RC filter network including resistor 1420 and capacitor 1422 for enhanced noise immunity. PMOS devices 1410 and 1414 form a PMOS mirror pair, and PMOS device 1414 conducts the same current conducted by PMOS device 1410. Resistors 1412 and 1418 match each other, and both drop the same voltage as each other. Resistors 1412 and 1418 are source degeneration resistors which improve matching, decrease noise, and increase the current mirror output impedance. The drain of PMOS device 1414 is coupled to the source of PMOS cascode device 1416, and the gate of PMOS cascode device 1416 is coupled to the gate of PMOS cascode device 1408. As a result, the mirrored current provided by PMOS device 1414 is conducted by PMOS cascode device 1416. The drain of PMOS cascode device 1416 is coupled to input source voltage VIN 1102 through resistor 1428. The voltage dropped across resistor 1428 will match the incoming voltage on line 1212 to buffer amplifier 1400. Accordingly, the voltage at node 1426 will be established at the voltage of VIN plus the voltage of Vsig, which matches the voltage applied on line 1212 coupled to the non-inverting terminal of buffer amplifier 1400. Node 1426 is coupled by a feedback path 1430 to the inverting input terminal of buffer amplifier 1400. Resistor 1428 establishes the feedback voltage at node 1426, and in this regard, resistor 1428 may be regarded as a feedback resistor for generating such feedback voltage. Again, buffer amplifier 1400 will work to ensure that its input terminals are at the same voltage through negative feedback. In the embodiment of FIG. 14, the feedback to the inverting input terminal of buffer amplifier 1400 is from node 1426 in the second leg (1414, 1416, 1428) of the current mirror, which ensures that the current flowing in the second leg is accurate. This scheme also reduces the magnitude of the voltage required from generated voltage source VBST. Thus, buffer amplifier 1400 controls the first current leg (1402, 1404, 1408, 1410, 1412) and the second mirrored current leg (1418, 1414, 1416, 1428) to each conduct a current which, when conducted by resistor 1428, drops a voltage equal to Vsig. All of the NMOS and PMOS devices included in such first and second current legs may be low voltage devices, since all of such devices operate in the limited voltage range between VBST and VIN. Noise-induced error is minimized since the mirrored PMOS devices have virtually identical voltages applied to their source, gate and drain terminals.

FIG. 14 includes a third current mirror leg formed by PMOS device 1436, PMOS device 1442, and PMOS device 1444. The source of PMOS device 1436 is coupled to the generated VBST voltage supply 1132 through resistor 1440; resistor 1440 is matched to resistors 1412 and 1418, and has a resistance value equal to that of resistors 1412 and 1418. Resistor 1440 likewise serves as a source degeneration resistor. The gate of PMOS device 1436 is coupled to the gates of PMOS device 1410 through an RC filter network including resistor 1434 and capacitor 1438; the values for resistor 1434 and capacitor 1438 may match the values for corresponding resistor 1420 and capacitor 1422. The drain of PMOS device 1436 is coupled to the source of PMOS cascode device 1442, and the gate of PMOS cascode device 1442 is coupled to the gates of PMOS devices 1408 and 1416. Accordingly, PMOS devices 1436 and 1442 in the third leg mirror the same current being conducted through the first two legs of the circuit. The drain of PMOS cascode device 1442 is coupled to the source of PMOS device 1444, the gate terminal of which is coupled to the input voltage source VIN. The drain terminal of PMOS device 1444 is coupled to node 1448, which is in turn coupled to ground through resistor 1446. Resistor 1446 is selected to have the same resistance value as that of resistor 1428. Accordingly, the voltage Vsig is dropped across resistor 1446, establishing node 1448 at the voltage Vsig above ground potential. It may be noted that the use of PMOS cascode devices 1408, 1416, and 1442 in the first, second, and third current legs, respectively, improve the current mirrors by increasing output resistance and ensuring that the drains of PMOS devices 1414 and 1436 match that of the drain of PMOS device 1410.

Thus, the level shifting circuitry of FIG. 14 transforms the voltage coming in on line 1212 (VIN plus Vsig) in the upper voltage domain to the voltage Vsig above ground in the lower voltage domain. In the embodiment shown in FIG. 14, the PMOS devices providing current to the resistors are matched much better, reducing any offset errors. In addition, the insertion of resistors 1412, 1418 and 1440 within the respective current legs improves matching and noise immunity, since any noise is dropped across such resistors.

As already noted, the circuitry used within the second level shifter LS2 1138 will be identical to the circuitry included in the first level shifter LS1 1134. The two level shifter circuits can be laid out within an integrated circuit in close proximity to each other to minimize offset errors between them. The two main benefits of the level shifter circuitry shown in FIG. 14 over that of the level shifter circuitry shown in FIG. 13 relate to lowering the magnitude of the generated VBST voltage and greater current mirror accuracy. In regard to the generated VBST voltage, if Vsig is assumed to be approximately 2.5V, then in the embodiment of FIG. 13, resistor 1304 also has approximately 2.5V across it. NMOS device 1302 requires 300 mV to be in good saturation, and PMOS device 1306 requires 0.7V VGS to function as a diode. This means that VBST needs to be 2.5V+0.3V+0.7V=3.5V minimum above VIN. In contrast, in the first leg of the embodiment of FIG. 14, NMOS devices 1402 and 1404 each need 0.7V, PMOS devices 1408 and 1410 each need 0.7V, and perhaps 0.2V is dropped across resistor 1412, for a total of 3V minimum above VIN. Moreover, the addition of NMOS device 1404 is optional, is shown only to raise the output of buffer amplifier 1400 higher for easing the design of buffer amplifier 1400. In the second leg of the embodiment of FIG. 14, resistor 1428 has 2.5V across it; PMOS devices 1414 and 1416 are not diode-connected, so they can work off 150 mV each. The voltage across upper resistor 1418 is about 0.2V, so the total voltage required in the second leg likewise about 3V. Thus, the level shifting circuit shown in FIG. 14 can work off a lower VBST supply voltage, easing the design of the circuitry generating supply voltage VBST. In addition, in the embodiment of FIG. 13, the reference current (or most accurate current) is set by the diode-connected PMOS device 1306 in the first leg. However, when this current is mirrored into the second leg, inaccuracies can occur as the voltages at the drains of PMOS devices 1306 and 1310 are not the same. In contrast, in the embodiment of FIG. 14, the reference current (or most accurate current) is in the mirrored second leg (1414, 1416, 1428), hence any errors between the diode-connected PMOS device 1410 and PMOS device 1414 do not matter since it is PMOS device 1414 that established the most accurate current. PMOS devices 1414 (in the second leg) and 1436 (in the third leg) will match each other better since they are connected to the first leg in the same manner; further, the connections of the second leg and the third leg to the first leg are both filtered. As a result, the current flowing into resistor 1446 will be more accurate using this scheme than using the scheme shown in FIG. 13. In addition, because R-C filters are applied to the gate terminals of both PMOS devices 1414 and 1436, and because the current in PMOS device 1436 is set by the current in PMOS device 1414 and its resistor 1428, noise immunity from generated supply voltage VBST is increased further.

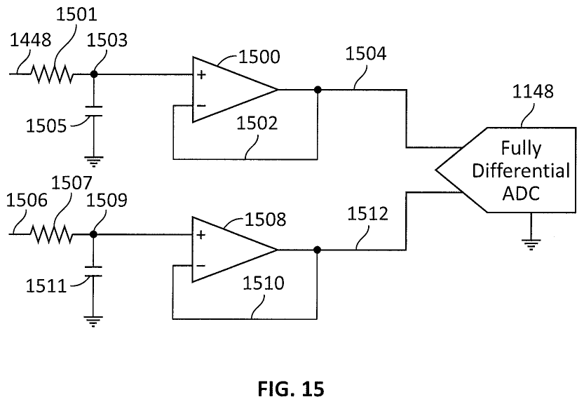

FIG. 15 illustrates circuitry for conditioning the signals provided by the first and second level shifter circuits (1134/1138) to a fully differential analog to digital converter. Signal 1448 (see FIG. 14) from the first level shifter circuit 1134 is coupled through an RC filter network consisting of resistor 1501 and capacitor 1505 to node 1503. The filtered voltage provided at node 1503 is provided to the non-inverting input terminal of a first unity gain buffer amplifier 1500 having an output terminal providing a first output signal on line 1504. The output terminal of buffer amplifier 1500 is fed back to the inverting terminal thereof. Likewise, signal 1506, corresponding to the voltage provided by the second level shifter circuit 1138 is coupled through an RC filter network consisting of resistor 1507 and capacitor 1511 to node 1509. The filtered voltage provided at node 1509 is provided to the non-inverting input terminal of a second unity gain buffer amplifier 1508 having an output terminal providing a first output signal on line 1512. The output terminal of buffer amplifier 1508 is fed back to the inverting terminal thereof. Output lines 1504 and 1512 may then be presented to the differential input terminals of fully differential analog to digital converter 1148 for conversion to a digital representation of the original voltage dropped across the sensing resistor 1104 (see FIG. 11), corresponding to a digital representation of the current being drawn by the switched mode power converter 1108.

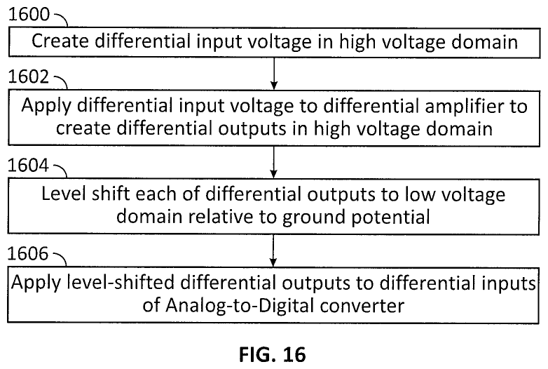

FIG. 16 illustrates a method for level shifting a differential voltage in an upper voltage domain to a lower voltage domain for processing by an analog to digital converter. In step 1600, a differential input voltage is created in an upper voltage domain. For example, this step may involve conducting a current across a resistor to generate a differential voltage dropped across the resistor as such current is drawn into a switched mode power converter from an input voltage source.

In step 1602, the differential input voltage created in step 1600 is applied to the input terminals of a differential amplifier to create a differential output voltage in an upper voltage domain across a pair of output terminals.

In step 1604, each of the output signals provided by the differential amplifier is separately level-shifted down to the lower voltage domain, typically proximate to ground potential.

In step 1606, the two level-shifted output signals are applied to the differential inputs of an analog to digital converter for conversion to a digital representation of the original differential voltage created in the upper voltage domain.

The novel differential level shifting circuitry and method described above may be incorporated into a system for charging a battery. In this case, load device 1124 in FIG. 11 represents a battery to be charged. The system includes switched-mode power converter 1108 of FIG. 11 for providing output current IOUT to charge the battery. Resistor 1104 conducts input current drawn by switched mode power converter 1108, and differential amplifier 1126 amplifies the voltage created across resistor 1104 to provide a differential amplified voltage across its output terminals 1128 and 1130 in an upper voltage domain. First level shifter 1134 receives the output signal provided by output line 1130 and provides a first output voltage on line 1140 relative to a reference potential (e.g., ground potential). Second level shifter 1138 receives the output signal provided by output line 1128 and provides a second output voltage on line 1142 relative to the reference potential. The first and second output voltages provided on lines 1140 and 1142 provide a differential level-shifted output voltage relative to the reference potential corresponding to input current drawn by switched mode power converter 1108. This differential level-shifted output voltage may be coupled to an analog to digital converter 1148, as shown in FIG. 11, to provide a digital representation of the input current drawn by switched mode power converter 1108.

It may be noted that while, in the present description of FIGS. 11-16, it is assumed that the switched mode power converter is acting to convert a higher voltage VIN to a lower voltage VOUT, the switched mode power converter could also be operated in a Boost mode without major modification. Referring to FIG. 11, switched mode power converter 1108 can be used to boost VOUT to VIN in Boost mode. This means that current in resistor 1104 flows in the opposite direction (from switched mode power converter 1108 to VIN 1100), and that node 1106 is at a higher voltage than node 1102, since current is flowing into VIN 1100 rather than out of VIN 1100. Nonetheless, the same current sensing circuit may be used. The polarity of the differential voltage created across resistor 1104 is reversed, but this is easily compensated for by swapping nodes 1140 and 1142 going into the fully differential ADC 1148. While it is also possible to compensate for the polarity reversal by swapping the signals on nodes 1128 and 1130 going into LS2 1138 and LS1 1134, it is much easier to make this swap in the lower voltage domain.

It is also possible, if desired, to use ADC 1148 in a fully differential mode whereby, when the voltages on nodes 1140 and 1142 are the same (i.e., no current flowing through resistor 1104), then ADC 1148 outputs a midpoint digital code corresponding to null, or zero. Then, when current does begin to flow through resistor 1104 in one direction or the other, ADC 1148 outputs a digital code that is either greater than the midpoint digital code corresponding to a positive current in buck mode operation, or less than the midpoint digital code corresponding to a negative current in boost mode operation.

Further aspects of the present disclosure include the following:

Aspect 1 includes a circuit comprising: a differential amplifier configured to operate from a first supply voltage and having first and second terminals configured to receive corresponding first and second signals, the differential amplifier having third and fourth terminals configured to provide a differential amplified voltage thereacross; a first level shifter comprising a first terminal coupled to the third terminal of the differential amplifier, and having a second terminal configured to provide a first output voltage relative to a reference potential; and a second level shifter comprising a first terminal coupled to the fourth terminal of the differential amplifier, and having a second terminal configured to provide a second output voltage relative to the reference potential; wherein the first output voltage and the second output voltage collectively correspond to a differential level-shifted output voltage relative to the reference potential.

Aspect 2 includes the circuit of aspect 1, further comprising: an input voltage source configured to provide a voltage level between the first supply voltage and the reference potential; a switched-mode power converter having a first terminal configured to receive an input current from the input voltage source; a resistive element coupled between the input voltage source and the first terminal of the switched mode power converter, and configured to conduct input current drawn by the first terminal of the switched mode power converter; and wherein the first terminal of the differential amplifier is coupled to the input voltage source on a first side of the resistive element, and the second terminal of the differential amplifier is coupled to the first terminal of the switched mode power converter on a second, opposing side of the resistive element.

Aspect 3 includes the circuit of any of aspects 1-2, wherein: the switched mode power converter comprises a multi-level converter.

Aspect 4 includes the circuit of any of aspects 1-3, wherein the resistive element is a sense resistor.

Aspect 5 includes the circuit of any of aspects 1-4 wherein the differential amplifier is configured to operate in a voltage domain between the first supply voltage and the input voltage source.

Aspect 6 includes the circuit of any of aspects 1-5 wherein the third terminal of the differential amplifier is configured to provide a first signal voltage relative to the input voltage source, and wherein the fourth terminal of the differential amplifier is configured to provide a second signal voltage relative to the input voltage source.

Aspect 7 includes the circuit of any of aspects 1-6 wherein the first level shifter comprises: a first operational amplifier configured to operate from the first supply voltage and having a first terminal coupled to the third terminal of the differential amplifier and configured to receive the first signal voltage, the first operational amplifier having a second terminal configured to provide an amplified output signal; a current mirror coupled to the second terminal of the first operational amplifier and configured to provide an output current related to the first signal voltage; and a first resistor coupled between the current mirror and the reference potential and configured to conduct the output current to produce the first output voltage as a first level-shifted voltage relative to the reference potential and related to the first signal voltage.

Aspect 8 includes the circuit of any of aspects 1-7 wherein: the first operational amplifier comprises a third terminal configured to receive a feedback voltage; the current mirror comprises a first current path configured to extend between the first supply voltage and the input voltage source, the first current path configured to conduct a first current through a feedback resistor, the feedback resistor configured to be coupled to the voltage input source, the feedback resistor also being configured to be coupled to the third terminal of the first operational amplifier and configured to provide a feedback voltage related to the first signal voltage; and the current mirror comprises a second current path configured to be coupled to the first supply voltage, the second current path configured to conduct a second current mirrored to the first current, the current mirror configured to supply the second current to the first resistor and configured to produce the first level-shifted voltage relative to the reference potential and related to the first signal voltage.

Aspect 9 includes the circuit of any of aspects 1-8 wherein: the first operational amplifier comprises a third terminal configured to receive a feedback voltage; the current mirror comprises a first current path configured to extend between the first supply voltage and the input voltage source, the first current path configured to conduct a first current therethrough controlled by the second terminal of the first operational amplifier; the current mirror comprises a second current path configured to extend between the first supply voltage and the input voltage source, the second current path configured to conduct a second current mirrored to the first current, the second current path configured to conduct the second current through a feedback resistor, the feedback resistor being configured to be coupled to the voltage input source, the feedback resistor also being configured to be coupled to the third terminal of the first operational amplifier and configured to provide a feedback voltage related to the first signal voltage; and the current mirror comprises a third current path configured to be coupled to the first supply voltage, the third current path configured to conduct a third current mirrored to the first current, the current mirror being configured to supply the third current to the first resistor and configured to produce the first level-shifted voltage relative to the reference potential and related to the first signal voltage.

Aspect 10 includes the circuit of any of aspects 1-9 further comprising: a first resistor configured to be coupled between the second terminal of the first level shifter and the reference potential and configured to conduct current sourced by the second terminal of the first level shifter, the first resistor being configured to provide the first output voltage relative to the reference potential; and a second resistor configured to be coupled between the second terminal of the second level shifter and the reference potential and configured to conduct current sourced by the second terminal of the second level shifter, the second resistor being configured to provide the second output voltage relative to the reference potential.

Aspect 11 includes the circuit of any of aspects 1-10, further comprising a differential analog to digital converter configured to provide first and second differential terminals configured to receive a differential voltage, the first differential terminal being configured to be coupled to the second terminal of the first level shifter, and the second differential terminal being configured to be coupled to the second terminal of the second level shifter, the differential analog to digital converter configured to provide a digital output signal corresponding to the differential, level-shifted output voltage.

Aspect 12 includes the circuit of any of aspects 1-11, further comprising: a first buffer amplifier configured to be coupled between the second terminal of the first level shifter and the first differential terminal of the differential analog to digital converter; and a second buffer amplifier configured to be coupled between the second terminal of the second level shifter and the second differential terminal of the differential analog to digital converter.

Aspect 13 includes a method comprising: applying a voltage across first and second terminals of a differential amplifier to produce a differential output voltage across third and fourth terminals thereof, the differential amplifier operating in an upper voltage domain proximate an upper voltage source, the differential amplifier configured to provide a third terminal voltage at its third terminal, and the differential amplifier configured to provide a fourth terminal voltage at its fourth terminal; level-shifting the third terminal voltage at the third terminal of the differential amplifier to a first level-shifted voltage in a lower voltage domain proximate to a ground potential; and level-shifting the fourth terminal voltage at the fourth terminal of the differential amplifier to a second level-shifted voltage in the lower voltage domain; wherein the first and second level-shifted voltages collectively provide a differential output voltage in the low voltage domain.

Aspect 14 includes the method of aspect 13, further comprising: providing a first voltage supply having a first supply voltage relative to ground potential; providing an input voltage source having a voltage between the first supply voltage and ground potential; providing a switched-mode power converter having a first terminal for drawing input current from the input voltage source; providing a resistive element between the input voltage source and the first terminal of the switched mode power converter for conducting input current drawn by the first terminal of the switched mode power converter; and applying the differential voltage created across the resistive element to the first and second terminals of the differential amplifier.

Aspect 15 includes the method of any of aspects 13-14, further comprising coupling the differential amplifier between the first supply voltage and the input voltage source.

Aspect 16 includes the method of any of aspects 13-15, wherein level-shifting the voltage at the third terminal of the differential amplifier further comprises: amplifying the voltage at the third terminal of the differential amplifier to provide a first amplified signal in the upper voltage domain; applying the first amplified signal to a current mirror to produce a first output current related to the voltage at the third terminal of the differential amplifier; and conducting the first output current through a first resistor coupled to ground potential to produce a first level-shifted voltage relative to ground potential and related to the voltage at the third terminal of the differential amplifier.

Aspect 17 includes the method of any of aspects 13-16, wherein level-shifting the voltage at the fourth terminal of the differential amplifier further comprises: amplifying the voltage at the fourth terminal of the differential amplifier to provide a second amplified signal in the upper voltage domain; applying the second amplified signal to a current mirror to produce a second output current related to the voltage at the fourth terminal of the differential amplifier; and conducting the second output current through a second resistor coupled to ground potential to produce a second level-shifted voltage relative to ground potential and related to the voltage at the fourth terminal of the differential amplifier.

Aspect 18 includes the method of any of aspects 13-17, further comprising applying the first and second level-shifted voltages as a differential voltage in the low voltage domain to differential terminals of a differential analog to digital converter.

Aspect 19 includes a system comprising: a battery; an input voltage source; a switched-mode power converter having a first terminal configured to receive an input current from the input voltage source, and a second terminal configured to charge the battery; a resistive element coupled between the input voltage source and the first terminal of the switched mode power converter, the resistive element configured to conduct input current drawn by the first terminal of the switched mode power converter; a differential amplifier configured to operate from a first supply voltage and having first and second terminals configured to receive corresponding first and second signals, the differential amplifier having third and fourth terminals configured to provide a differential amplified voltage thereacross, the first terminal of the differential amplifier coupled to the input voltage source on a first side of the resistive element, and the second terminal of the differential amplifier coupled to the first terminal of the switched mode power converter on a second, opposing side of the resistive element; a first level shifter comprising a first terminal coupled to the third terminal of the differential amplifier, and having a second terminal configured to provide a first output voltage relative to a reference potential; a second level shifter comprising a first terminal coupled to the fourth terminal of the differential amplifier, and having a second terminal configured to provide a second output voltage relative to the reference potential; and wherein the first output voltage and the second output voltage collectively correspond to a differential level-shifted output voltage relative to the reference potential, the differential level-shifted output voltage corresponding to input current drawn by the first terminal of the switched mode power converter.

### General Benefits and Advantages of Multi-Level Power Converters

Embodiments of the current invention improve the power density and/or power efficiency of incorporating circuits and circuit modules or blocks. As a person of ordinary skill in the art should understand, a system architecture is beneficially impacted utilizing embodiments of the current invention in critical ways, including lower power and/or longer battery life. The current invention therefore specifically encompasses system-level embodiments that are creatively enabled by inclusion in a large system design and application.

More particularly, multi-level power converters provide or enable numerous benefits and advantages, including:
adaptability to applications in which input and/or output voltages may have a wide dynamic-range (e.g., varying battery input voltage levels, varying output voltages);
efficiency improvements on the run-time of devices operating on portable electrical energy sources (batteries, generators or fuel cells using liquid or gaseous fuels, solar cells, etc.);
efficiency improvements where efficiency is important for thermal management, particularly to protect other components (e.g., displays, nearby ICs) from excessive heat;
enabling design optimizations for power efficiency, power density, and form-factor of the power converter—for example, smaller-size multi-level power converters may allow placing power converters in close proximity to loads, thus increasing efficiency, and/or to lower an overall bill of materials;
the ability to take advantage of the performance of smaller, low voltage transistors;
adaptability to applications in which power sources can vary widely, such as batteries, other power converters, generators or fuel cells using liquid or gaseous fuels, solar cells, line voltage (AC), and DC voltage sources (e.g., USB, USB-C, power-over Ethernet, etc.);
adaptability to applications in which loads may vary widely, such as ICs in general (including microprocessors and memory ICs), electrical motors and actuators, transducers, sensors, and displays (e.g., LCDs and LEDs of all types);
the ability to be implemented in a number of IC technologies (e.g., MOSFETs, GaN, GaAs, and bulk silicon) and packaging technologies (e.g., flip chips, ball-grid arrays, wafer level scale chip packages, wide-fan out packaging, and embedded packaging).

The advantages and benefits of multi-level power converters enable usage in a wide array of applications. For example, applications of multi-level power converters include portable and mobile computing and/or communication products and components (e.g., notebook computers, ultra-book computers, tablet devices, and cell phones), displays (e.g., LCDs, LEDs), radio-based devices and systems (e.g., cellular systems, WiFi, Bluetooth, Zigbee, Z-Wave, and GPS-based devices), wired network devices and systems, data centers (e.g., for battery-backup systems and/or power conversion for processing systems and/or electronic/optical networking systems), internet-of-things (IOT) devices (e.g., smart switches and lights, safety sensors, and security cameras), household appliances and electronics (e.g., set-top boxes, battery-operated vacuum cleaners, appliances with built-in radio transceivers such as washers, dryers, and refrigerators), AC/DC power converters, electric vehicles of all types (e.g., for drive trains, control systems, and/or infotainment systems), and other devices and systems that utilize portable electricity generating sources and/or require power conversion.

Radio system usage includes wireless RF systems (including base stations, relay stations, and hand-held transceivers) that use various technologies and protocols, including various types of orthogonal frequency-division multiplexing (“OFDM”), quadrature amplitude modulation (“QAM”), Code-Division Multiple Access (“CDMA”), Time-Division Multiple Access (“TDMA”), Wide Band Code Division Multiple Access (“W-CDMA”), Global System for Mobile Communications (“GSM”), Long Term Evolution (“LTE”), 5G, and WiFi (e.g., 802.11a, b, g, ac, ax), as well as other radio communication standards and protocols.

### Programmable Embodiments

Some or all aspects of the invention, particularly the Multi-Level Switch State Selector 1014 of FIG. 10, may be implemented in hardware or software, or a combination of both (e.g., programmable logic arrays). Unless otherwise specified, the algorithms included as part of the invention are not inherently related to any particular computer or other apparatus. In particular, various general purpose computing machines may be used with programs written in accordance with the teachings herein, or it may be more convenient to use a special purpose computer or special-purpose hardware (such as integrated circuits) to perform particular functions. Thus, embodiments of the invention may be implemented in one or more computer programs (i.e., a set of instructions or codes) executing on one or more programmed or programmable computer systems (which may be of various architectures, such as distributed, client/server, or grid) each comprising at least one processor, at least one data storage system (which may include volatile and non-volatile memory and/or storage elements), at least one input device or port, and at least one output device or port. Program instructions or code may be applied to input data to perform the functions described in this disclosure and generate output information. The output information may be applied to one or more output devices in known fashion.

Each such computer program may be implemented in any desired computer language (including machine, assembly, or high-level procedural, logical, or object-oriented programming languages) to communicate with a computer system, and may be implemented in a distributed manner in which different parts of the computation specified by the software are performed by different computers or processors. In any case, the computer language may be a compiled or interpreted language. Computer programs implementing some or all of the invention may form one or more modules of a larger program or system of programs. Some or all of the elements of the computer program can be implemented as data structures stored in a computer readable medium or other organized data conforming to a data model stored in a data repository.

Each such computer program may be stored on or downloaded to (for example, by being encoded in a propagated signal and delivered over a communication medium such as a network) a tangible, non-transitory storage media or device (e.g., solid state memory media or devices, or magnetic or optical media) for a period of time (e.g., the time between refresh periods of a dynamic memory device, such as a dynamic RAM, or semi-permanently or permanently), the storage media or device being readable by a general or special purpose programmable computer or processor for configuring and operating the computer or processor when the storage media or device is read by the computer or processor to perform the procedures described above. The inventive system may also be considered to be implemented as a non-transitory computer-readable storage medium, configured with a computer program, where the storage medium so configured causes a computer or processor to operate in a specific or predefined manner to perform the functions described in this disclosure.

### Fabrication Technologies & Options

In various embodiments of multi-level power converters, it may be beneficial to use specific types of capacitors, particularly for the fly capacitors. For example, it is generally useful for such capacitors to have low equivalent series resistance (ESR), low DC bias degradation, high capacitance, and small volume. Low ESR is especially important for multi-level power converters that incorporate additional switches and fly capacitors to increase the number of voltage levels. Selection of a particular capacitor should be made after consideration of specifications for power level, efficiency, size, etc. Various types of capacitor technologies may be used, including ceramic (including multi-layer ceramic capacitors), electrolytic capacitors, film capacitors (including power film capacitors), and IC-based capacitors. Capacitor dielectrics may vary as needed for particular applications, and may include dielectrics that are paraelectric, such as silicon dioxide (SiO₂), hafnium dioxide (HFO₂), or aluminum oxide Al₂O₃. In addition, multi-level power converter designs may beneficially utilize intrinsic parasitic capacitances (e.g., intrinsic to the power FETs) in conjunction with or in lieu of designed capacitors to reduce circuit size and/or increase circuit performance. Selection of capacitors for multi-level power converters may also take into account such factors as capacitor component variations, reduced effective capacitance with DC bias, and ceramic capacitor temperature coefficients (minimum and maximum temperature operating limits, and capacitance variation with temperature).

Similarly, in various embodiments of multi-level power converters, it may be beneficial to use specific types of inductors. For example, it is generally useful for the inductors to have low DC equivalent resistance, high inductance, and small volume.

The controller(s) used to control startup and operation of a multi-level power converter may be implemented as a microprocessor, a microcontroller, a digital signal processor (DSP), register-transfer level (RTL) circuitry, and/or combinatorial logic.

The term “MOSFET”, as used in this disclosure, includes any field effect transistor (FET) having an insulated gate whose voltage determines the conductivity of the transistor, and encompasses insulated gates having a metal or metal-like, insulator, and/or semiconductor structure. The terms “metal” or “metal-like” include at least one electrically conductive material (such as aluminum, copper, or other metal, or highly doped polysilicon, graphene, or other electrical conductor), “insulator” includes at least one insulating material (such as silicon oxide or other dielectric material), and “semiconductor” includes at least one semiconductor material.

As used in this disclosure, the term “radio frequency” (RF) refers to a rate of oscillation in the range of about 3 kHz to about 300 GHz. This term also includes the frequencies used in wireless communication systems. An RF frequency may be the frequency of an electromagnetic wave or of an alternating voltage or current in a circuit.

With respect to the figures referenced in this disclosure, the dimensions for the various elements are not to scale; some dimensions have been greatly exaggerated vertically and/or horizontally for clarity or emphasis. In addition, references to orientations and directions (e.g., “top”, “bottom”, “above”, “below”, “lateral”, “vertical”, “horizontal”, etc.) are relative to the example drawings, and not necessarily absolute orientations or directions.

Various embodiments of the invention can be implemented to meet a wide variety of specifications. Unless otherwise noted above, selection of suitable component values is a matter of design choice. Various embodiments of the invention may be implemented in any suitable integrated circuit (IC) technology (including but not limited to MOSFET structures), or in hybrid or discrete circuit forms. Integrated circuit embodiments may be fabricated using any suitable substrates and processes, including but not limited to standard bulk silicon, high-resistivity bulk CMOS, silicon-on-insulator (SOI), and silicon-on-sapphire (SOS). Unless otherwise noted above, embodiments of the invention may be implemented in other transistor technologies such as bipolar, BiCMOS, LDMOS, BCD, GaAs HBT, GaN HEMT, GaAs pHEMT, and MESFET technologies. However, embodiments of the invention are particularly useful when fabricated using an SOI or SOS based process, or when fabricated with processes having similar characteristics. Fabrication in CMOS using SOI or SOS processes enables circuits with low power consumption, the ability to withstand high power signals during operation due to FET stacking, good linearity, and high frequency operation (i.e., radio frequencies up to and exceeding 300 GHz). Monolithic IC implementation is particularly useful since parasitic capacitances generally can be kept low (or at a minimum, kept uniform across all units, permitting them to be compensated) by careful design.

Voltage levels may be adjusted, and/or voltage and/or logic signal polarities reversed, depending on a particular specification and/or implementing technology (e.g., NMOS, PMOS, or CMOS, and enhancement mode or depletion mode transistor devices). Component voltage, current, and power handling capabilities may be adapted as needed, for example, by adjusting device sizes, serially “stacking” components (particularly FETs) to withstand greater voltages, and/or using multiple components in parallel to handle greater currents. Additional circuit components may be added to enhance the capabilities of the disclosed circuits and/or to provide additional functionality without significantly altering the functionality of the disclosed circuits.

Circuits and devices in accordance with the present invention may be used alone or in combination with other components, circuits, and devices. Embodiments of the present invention may be fabricated as integrated circuits (ICs), which may be encased in IC packages and/or in modules for ease of handling, manufacture, and/or improved performance. In particular, IC embodiments of this invention are often used in modules in which one or more of such ICs are combined with other circuit blocks (e.g., filters, amplifiers, passive components, and possibly additional ICs) into one package. The ICs and/or modules are then typically combined with other components, often on a printed circuit board, to form part of an end product such as a cellular telephone, laptop computer, or electronic tablet, or to form a higher-level module which may be used in a wide variety of products, such as vehicles, test equipment, medical devices, etc. Through various configurations of modules and assemblies, such ICs typically enable a mode of communication, often wireless communication.

A number of embodiments of the disclosure have been described. It is to be understood that various modifications may be made without departing from the spirit and scope of the disclosure. For example, some of the steps described above may be order independent, and thus can be performed in an order different from that described. Further, some of the steps described above may be optional. Various activities described with respect to the methods identified above can be executed in repetitive, serial, and/or parallel fashion.

It is to be understood that the foregoing description is intended to illustrate and not to limit the scope of the disclosure, which is defined by the scope of the following claims, and that other embodiments are within the scope of the claims. In particular, the scope of the disclosure includes any and all feasible combinations of one or more of the processes, machines, manufactures, or compositions of matter set forth in the claims below. (Note that the parenthetical labels for claim elements are for ease of referring to such elements, and do not in themselves indicate a particular required ordering or enumeration of elements; further, such labels may be reused in dependent claims as references to additional elements without being regarded as starting a conflicting labeling sequence).

What is claimed is:

1. A circuit comprising:
a) a differential amplifier configured to operate from a first supply voltage, the differential amplifier having first and second terminals configured to receive corresponding first and second signals, the differential amplifier having third and fourth terminals configured to provide a differential amplified voltage thereacross;
b) a first level shifter comprising a first terminal coupled to the third terminal of the differential amplifier, and having a second terminal configured to provide a first output voltage relative to a reference potential; and
c) a second level shifter comprising a first terminal coupled to the fourth terminal of the differential amplifier, and having a second terminal configured to provide a second output voltage relative to the reference potential;
d) wherein the first output voltage and the second output voltage collectively correspond to a differential level-shifted output voltage relative to the reference potential.

2. The circuit of claim 1 further comprising:
a) an input voltage source configured to provide a voltage level between the first supply voltage and the reference potential;
b) a switched-mode power converter having a first terminal configured to receive an input current from the input voltage source;
c) a resistive element coupled between the input voltage source and the first terminal of the switched mode power converter, the resistive element configured to conduct input current drawn by the first terminal of the switched mode power converter; and
d) wherein the first terminal of the differential amplifier is coupled to the input voltage source on a first side of the resistive element, and the second terminal of the differential amplifier is coupled to the first terminal of the switched mode power converter on a second, opposing side of the resistive element.

3. The circuit of claim 2 wherein the switched mode power converter comprises a multi-level converter.

4. The circuit of claim 2 wherein the resistive element is a sense resistor.

5. The circuit of claim 2 wherein the differential amplifier is configured to operate in a voltage domain between the first supply voltage and the input voltage source.

6. The circuit of claim 2 wherein the third terminal of the differential amplifier is configured to provide a first signal voltage relative to the input voltage source, and wherein the fourth terminal of the differential amplifier is configured to provide a second signal voltage relative to the input voltage source.

7. The circuit of claim 6 wherein the first level shifter comprises:
a) a first operational amplifier configured to operate from the first supply voltage and having a first terminal coupled to the third terminal of the differential amplifier and configured to receive the first signal voltage, the first operational amplifier having a second terminal configured to provide an amplified output signal;
b) a current mirror coupled to the second terminal of the first operational amplifier, the current mirror configured to provide an output current related to the first signal voltage; and
c) a first resistor coupled between the current mirror and the reference potential and configured to conduct the output current to produce the first output voltage as a first level-shifted voltage relative to the reference potential and related to the first signal voltage.

8. The circuit of claim 7 wherein:
a) the first operational amplifier comprises a third terminal configured to receive a feedback voltage;
b) the current mirror comprises a first current path configured to extend between the first supply voltage and the input voltage source, the first current path configured to conduct a first current through a feedback resistor, the feedback resistor configured to be coupled to the voltage input source, the feedback resistor also being configured to be coupled to the third terminal of the first operational amplifier and configured to provide a feedback voltage related to the first signal voltage; and
c) the current mirror comprises a second current path configured to be coupled to the first supply voltage, the second current path configured to conduct a second current mirrored to the first current, the current mirror configured to supply the second current to the first resistor and configured to produce the first level-shifted voltage relative to the reference potential and related to the first signal voltage.

9. The circuit of claim 7 wherein:
a) the first operational amplifier comprises a third terminal configured to receive a feedback voltage;
b) the current mirror comprises a first current path configured to extend between the first supply voltage and the input voltage source, the first current path configured to conduct a first current therethrough controlled by the second terminal of the first operational amplifier;
c) the current mirror comprises a second current path configured to extend between the first supply voltage and the input voltage source, the second current path configured to conduct a second current mirrored to the first current, the second current path configured to conduct the second current through a feedback resistor, the feedback resistor being configured to be coupled to the voltage input source, the feedback resistor also being configured to be coupled to the third terminal of the first operational amplifier and configured to provide a feedback voltage related to the first signal voltage; and
d) the current mirror comprising a third current path configured to be coupled to the first supply voltage, the third current path configured to conduct a third current mirrored to the first current, the current mirror being configured to supply the third current to the first resistor and configured to produce the first level-shifted voltage relative to the reference potential and related to the first signal voltage.

10. The circuit of claim 1 further comprising:
a) a first resistor configured to be coupled between the second terminal of the first level shifter and the reference potential and configured to conduct current sourced by the second terminal of the first level shifter, the first resistor being configured to provide the first output voltage relative to the reference potential; and
b) a second resistor configured to be coupled between the second terminal of the second level shifter and the reference potential and configured to conduct current sourced by the second terminal of the second level shifter, the second resistor being configured to provide the second output voltage relative to the reference potential.

11. The circuit of claim 10 further comprising a differential analog to digital converter configured to provide first and second differential terminals configured to receive a differential voltage, the first differential terminal being configured to be coupled to the second terminal of the first level shifter, and the second differential terminal being configured to be coupled to the second terminal of the second level shifter, the differential analog to digital converter configured to provide a digital output signal corresponding to the differential, level-shifted output voltage.

12. The circuit of claim 11 further comprising:
a) a first buffer amplifier configured to be coupled between the second terminal of the first level shifter and the first differential terminal of the differential analog to digital converter; and
b) a second buffer amplifier configured to be coupled between the second terminal of the second level shifter and the second differential terminal of the differential analog to digital converter.

13. A method comprising:
a) applying a voltage across first and second terminals of a differential amplifier to produce a differential output voltage across third and fourth terminals thereof, the differential amplifier operating in an upper voltage domain proximate an upper voltage source, the differential amplifier configured to provide a third terminal voltage at its third terminal, and the differential amplifier configured to provide a fourth terminal voltage at its fourth terminal;
b) level-shifting the third terminal voltage at the third terminal of the differential amplifier to a first level-shifted voltage in a lower voltage domain proximate to a ground potential; and
c) level-shifting the fourth terminal voltage at the fourth terminal of the differential amplifier to a second level-shifted voltage in the lower voltage domain;
wherein the first and second level-shifted voltages collectively provide a differential output voltage in the low voltage domain.

14. The method recited by claim 13, further comprising:
a) providing a first voltage supply having a first supply voltage relative to ground potential;
b) providing an input voltage source having a voltage between the first supply voltage and ground potential;
c) providing a switched-mode power converter having a first terminal for drawing input current from the input voltage source;
d) providing a resistive element between the input voltage source and the first terminal of the switched mode power converter for conducting input current drawn by the first terminal of the switched mode power converter; and
e) applying the differential voltage created across the resistive element to the first and second terminals of the differential amplifier.

15. The method recited by claim 14, further comprising coupling the differential amplifier between the first supply voltage and the input voltage source.

16. The method recited by claim 13, wherein level-shifting the voltage at the third terminal of the differential amplifier further comprises:
a) amplifying the voltage at the third terminal of the differential amplifier to provide a first amplified signal in the upper voltage domain;
b) applying the first amplified signal to a current mirror to produce a first output current related to the voltage at the third terminal of the differential amplifier; and
c) conducting the first output current through a first resistor coupled to ground potential to produce a first level-shifted voltage relative to ground potential and related to the voltage at the third terminal of the differential amplifier.

17. The method recited by claim 16, wherein level-shifting the voltage at the fourth terminal of the differential amplifier further comprises:
a) amplifying the voltage at the fourth terminal of the differential amplifier to provide a second amplified signal in the upper voltage domain;
b) applying the second amplified signal to a current mirror to produce a second output current related to the voltage at the fourth terminal of the differential amplifier; and
c) conducting the second output current through a second resistor coupled to ground potential to produce a second level-shifted voltage relative to ground potential and related to the voltage at the fourth terminal of the differential amplifier.

18. The method recited by claim 13, further comprising applying the first and second level-shifted voltages as a differential voltage in the low voltage domain to differential terminals of a differential analog to digital converter.

19. A system comprising:
a) a battery;
b) an input voltage source;
c) a switched-mode power converter having a first terminal configured to receive an input current from the input voltage source, and a second terminal configured to charge the battery;
d) a resistive element coupled between the input voltage source and the first terminal of the switched mode power converter, the resistive element configured to conduct input current drawn by the first terminal of the switched mode power converter;
e) a differential amplifier configured to operate from a first supply voltage, the differential amplifier having first and second terminals configured to receive corresponding first and second signals, the differential amplifier having third and fourth terminals configured to provide a differential amplified voltage thereacross, the first terminal of the differential amplifier coupled to the input voltage source on a first side of the resistive element, and the second terminal of the differential amplifier coupled to the first terminal of the switched mode power converter on a second, opposing side of the resistive element;
f) a first level shifter comprising a first terminal coupled to the third terminal of the differential amplifier, and having a second terminal configured to provide a first output voltage relative to a reference potential;
g) a second level shifter comprising a first terminal coupled to the fourth terminal of the differential amplifier, and having a second terminal configured to provide a second output voltage relative to the reference potential; and
h) wherein the first output voltage and the second output voltage collectively correspond to a differential level-shifted output voltage relative to the reference potential, the differential level-shifted output voltage corresponding to input current drawn by the first terminal of the switched mode power converter.
